(19) United States
(12) Patent Application Publication
(10) Pub. No.: US 2025/0151289 A1
(43) Pub. Date: May 8, 2025

(54) SEMICONDUCTOR DEVICES, THREE-DIMENSIONAL MEMORY DEVICES, AND METHODS FOR FORMING THE SAME

(71) Applicant: YANGTZE MEMORY TECHNOLOGIES CO., LTD., Wuhan (CN)

(72) Inventors: Jiangang Ke, Wuhan (CN); Tingting Gao, Wuhan (CN); Wenxi Zhou, Wuhan (CN); Zhiliang Xia, Wuhan (CN); Zongliang Huo, Wuhan (CN)

(21) Appl. No.: 18/388,433

(22) Filed: Nov. 9, 2023

(30) Foreign Application Priority Data
Nov. 2, 2023 (CN) 202311456332.6

(51) Int. Cl. H10B 80/00; H01L 23/00; H01L 25/00; H01L 25/065; H01L 25/18; H10B 43/27

(52) U.S. Cl. CPC H10B 80/00; H01L 24/08; H01L 24/80; H01L 25/0657; H01L 25/18; H01L 25/50; H10B 43/27; H01L 2224/08145; H01L 2224/80895; H01L 2224/80896; H01L 2225/06541; H01L 2924/1431; H01L 2924/14511

(57) ABSTRACT

A semiconductor device includes a semiconductor layer, a stack structure over the semiconductor layer, a first contact structure, and a second contact structure. The stack structure includes alternating first layers and first dielectric layers. The stack structure includes a first portion and a second portion adjacent to the first portion, the first layers of the first portion include second dielectric layers, and the first layers of the second portion include conductive layers. The first contact structure extends through the first portion and the semiconductor layer. The second contact structure extends through a part of the first portion and connects with one of the conductive layers.

### CROSS-REFERENCE TO RELATED APPLICATIONS

This application claims the benefit of priority to Chinese Application No. 202311456332.6, filed on Nov. 2, 2023, which is incorporated herein by reference in its entirety.

### BACKGROUND

The present disclosure relates to semiconductor devices with a plurality of contact structures, three-dimensional (3D) memory devices, and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral devices for controlling signals to and from the memory array.

### SUMMARY

In one aspect, a semiconductor device includes a semiconductor layer, a stack structure over the semiconductor layer, a first contact structure, and a second contact structure. The stack structure includes alternating first layers and first dielectric layers. The stack structure includes a first portion and a second portion adjacent to the first portion, the first layers of the first portion include second dielectric layers, and the first layers of the second portion include conductive layers. The first contact structure extends through the first portion and the semiconductor layer. The second contact structure extends through a part of the first portion and connects with one of the conductive layers.

In some implementations, the first contact structure includes a first segment and a second segment connected with the first segment in a first direction, the first segment includes a first end contacting the second segment, and the second segment includes a second end contacting the first segment. A size of the first end is greater than a size of the second end in a second direction perpendicular to the first direction.

In some implementations, the first segment further includes a third end away from the first end, and the second segment further includes a fourth end away from the second end. A size of the third end is greater than a size of the first end in the second direction, and a size of the second end is greater than a size of the fourth end in the second direction.

In some implementations, the first segment is located on a side of the second segment away from the semiconductor layer.

In some implementations, the second contact structure includes a vertical contact structure and a lateral contact structure connecting to the vertical contact structure. The vertical contact structure extends in a same direction as the first contact structure. The lateral contact structure connects with the one of the conductive layers.

In some implementations, the first contact structure includes a first joint in a first stack pair, and the vertical contact structure extends to the first stack pair. The first stack pair is a pair including one of the first dielectric layers and one of the first layers in contact with the one of the first dielectric layers.

In some implementations, the semiconductor device further includes a third contact structure extending through a portion of the first portion. The third contact structure is connected with a second stack pair, and the first contact structure includes a second joint in the second stack pair.

In some implementations, the first contact structure includes a first conductor layer and a first spacer surrounding the first conductor layer. The second contact structure includes a second conductor layer and a second spacer surrounding the second conductor layer. The first spacer and the second spacer include a same material, and the first conductor layer and the second conductor layer include a same material.

In some implementations, the first contact structure further includes a first filler body surrounded by the first conductor layer.

In some implementations, the second contact structure further includes a second filler body surrounded by the second conductor layer, and the first filler body and the second filler body include a same material.

In some implementations, the semiconductor device further includes channel structures extending through the second portion into the semiconductor layer.

In some implementations, in a vertical direction, a length of the first contact structure is greater than a length of the channel structures.

In some implementations, the second portion includes a first part and a second part separated from the first part. The first portion connects the first part and the second part.

In some implementations, the semiconductor device further includes a peripheral circuit connected with the first contact structure.

In some implementations, the semiconductor device further includes a first connection layer and a second connection layer, the first connection layer connected with the first contact structure, the second connection layer connected with the peripheral circuit. The first connection layer is bonded with the second connection layer.

In some implementations, the peripheral circuit is disposed under the stack structure, and the first contact structure extends through the semiconductor layer to connect with the peripheral circuit.

In another aspect, a memory device includes a first semiconductor structure, a second semiconductor structure, and a first peripheral circuit. The first semiconductor structure includes a first stack structure including alternating first and second dielectric layers and a first contact structure extending through the first stack structure. The second semiconductor structure includes a second stack structure including alternating third and four dielectric layers and a second contact structure extending through the second stack structure. The first peripheral circuit is connected with the first contact structure and the second contact structure.

In some implementations, the first peripheral circuit is bonded with the first semiconductor structure, and the first peripheral circuit includes a first connect structure between the first semiconductor structure and the second semiconductor structure.

In some implementations, the memory device further includes a second peripheral circuit bonded with the second semiconductor structure. The second peripheral circuit includes a second connect structure connecting the second contact structure.

In some implementations, the second semiconductor structure is between the first peripheral circuit and the second peripheral circuit.

In some implementations, the first peripheral circuit further includes a semiconductor layer and an interconnect structure extending through the semiconductor layer.

In some implementations, the first contact structure includes an insulating filler and a conductor layer surrounding the insulating filler, the interconnect structure includes a conductive filler and a spacer surrounding the conductive filler, and the conductor layer is connected with the conductive filler.

In some implementations, the first contact structure includes a first segment and a second segment connected with the first segment in a first direction, the first segment includes a first end contacting the second segment, the second segment includes a second end contacting the first segment, and a size of the first end is greater than a size of the second end in a second direction perpendicular to the first direction.

In some implementations, the first segment further includes a third end away from the first end, the second segment further includes a fourth end away from the second end, a size of the third end is greater than a size of the first end in the second direction, and a size of the second end is greater than a size of the fourth end in the second direction.

In some implementations, the first stack structure is disposed over a semiconductor layer, and the first segment is located on a side of the second segment away from the semiconductor layer.

In some implementations, the first semiconductor structure further includes a third contact structure extending through a part of the first stack structure. The third contact structure includes a vertical contact structure and a lateral contact structure connecting to the vertical contact structure, and the vertical contact structure extends in a same direction as the first contact structure.

In some implementations, the first contact structure includes a first joint in a first stack pair, and the vertical contact structure extends to the first stack pair. The first stack pair is a pair including one of the first dielectric layers and one of the second dielectric layers in contact with the one of the first dielectric layers.

In some implementations, the memory device further includes a fourth contact structure extending through a portion of the first stack structure. The fourth contact structure is connected with a second stack pair, and the first contact structure includes a second joint in the second stack pair.

In some implementations, the first contact structure includes a first conductor layer and a first spacer surrounding the first conductor layer. The second contact structure includes a second conductor layer and a second spacer surrounding the second conductor layer. The third contact structure includes a second conductor layer and a second spacer surrounding the second conductor layer. The first spacer and the second spacer include a same material, and the first conductor layer and the second conductor layer include a same material.

In some implementations, the first contact structure further includes a first filler body surrounded by the first conductor layer.

In still another aspect, a method of forming a semiconductor device is disclosed. The method includes forming a stack structure including alternating first and second dielectric layers. The method also includes forming a first contact hole extending through the stack structure. The method further includes forming second contact holes extending through a part of the stack structure during the formation of the first contact hole.

In some implementations, forming the first contact hole and forming the second contact holes during the formation of the first contact hole include etching the stack structure with a first mask to form a first opening and one or more second openings which extend into the stack structure, where the second contact holes include the one or more second openings, and etching the first opening with a second mask to form a third opening which extends further through the stack structure, where the first contact hole includes the first and third openings.

In some implementations, forming the second contact holes further includes etching the stack structure with a third mask to form one or more fourth openings which extend into the stack structure. The second contact holes further include the one or more fourth openings.

In some implementations, the method further includes forming a first contact structure in the first contact hole, and forming second contact structures in the second contact holes, respectively, during the formation of the first contact structure.

In some implementations, the first contact structure includes a first spacer, a first conductor layer surrounded by the first spacer, and a first filler body surrounded by the first conductor layer. The second contact structures include second spacers, second conductor layers surrounded by the second spacers, lateral contact structures connected with the second conductor layers, and second filler bodies surrounded by the second conductor layers, respectively.

In some implementations, forming the first contact structure and forming the second contact structures include: forming the first spacer on a sidewall of the first contact hole, and forming the second spacers on sidewalls of the second contact holes, respectively; forming the lateral contact structures of the second contact structures below bottoms of the second contact holes; forming the first conductor layer over the first spacer and a bottom of the first contact hole, and forming the second conductor layers over the second spacers and the lateral contact structures, respectively; and filling a remaining portion of the first contact hole with the first filler body, and filling remaining portions of the second contact holes with the second filler bodies, respectively.

In some implementations, forming the lateral contact structures of the second contact structures below the bottoms of the second contact holes includes removing part of respective second dielectric layers exposed at the bottoms of the second contact holes to form lateral recesses, respectively, and filling the lateral recesses by depositing conductive materials through the second contact holes to form the lateral contact structures, respectively.

In some implementations, forming the first contact structure and forming the second contact structures further include forming a first contact pad on the first conductor layer and the first filler body, and forming second contact pads on the second conductor layers and the second filler bodies, respectively.

In still yet another aspect, a semiconductor device includes a stack structure, a first contact structure, and a second contact structure. The stack structure includes alternating first and second dielectric layers. The first contact structure extends through the stack structure, and includes a first conductor layer and a first spacer surrounding a sidewall of the first conductor layer. The second contact structure extends through a part of the stack structure, and includes a second conductor layer and a second spacer surrounding a sidewall of the second conductor layer. The first spacer and the second spacer include a first material, and the first conductor layer and the second conductor layer include a second material different from the first material.

In some implementations, the first contact structure includes a first segment and a second segment connected with the first segment in a first direction, the first segment includes a first end contacting the second segment, and the second segment includes a second end contacting the first segment. A size of the first end is greater than a size of the second end in a second direction perpendicular to the first direction.

In some implementations, the first segment further includes a third end away from the first end, and the second segment further includes a fourth end away from the second end. A size of the third end is greater than a size of the first end in the second direction, and a size of the second end is greater than a size of the fourth end in the second direction.

In some implementations, the first stack structure is disposed over a semiconductor layer, and the first segment is located on a side of the second segment away from the semiconductor layer.

In some implementations, the second contact structure includes a vertical contact structure and a lateral contact structure connecting to the vertical contact structure, and the vertical contact structure extends in a same direction as the first contact structure.

In some implementations, the first contact structure includes a first joint in a first stack pair, and the vertical contact structure extends to the first stack pair. The first stack pair is a pair including one of the first dielectric layers and one of the second dielectric layers in contact with the one of the first dielectric layers.

In some implementations, the semiconductor device further includes a third contact structure extending through the stack structure. The third contact structure is connected with a second stack pair, and the first contact structure includes a second joint in the second stack pair.

In some implementations, the semiconductor device further includes a peripheral circuit connected with the first contact structure and the second contact structure.

In still yet another aspect, a memory device includes a first contact structure and a second contact structure. The first contact structure includes an insulating filler and a conductor layer surrounding the insulating filler and extending in a first direction. The second contact structure includes a conductive filler and a spacer surrounding a sidewall of the conductive filler and extending in the first direction. The conductor layer connects with the conductive filler.

In still yet another aspect, a semiconductor device includes a semiconductor layer, a stack structure over the semiconductor layer and including alternating conductive layers and dielectric layers, a first contact structure extending through the stack structure and including a first conductor layer and a first spacer surrounding a sidewall of the first conductor layer, and a second contact structure extending through a portion of the stack structure and including a second conductor layer and a second spacer surrounding a sidewall of the second conductor layer. The second conductor layer connects with one of the conductive layers, and the first conductor layer and the conductive layers are separated by the first spacer.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates a plan view of a semiconductor structure having a plurality of contact structures, according to some aspects of the present disclosure.

FIG. 1B illustrates another plan view of a semiconductor structure having a plurality of contact structures, according to some aspects of the present disclosure.

FIG. 2A illustrates a cross-sectional side view of a first example implementation of contact structures, according to some aspects of the present disclosure.

FIG. 2B illustrates a cross-sectional side view of a first contact structure in FIG. 2A, according to some aspects of the present disclosure.

FIG. 2C illustrates a cross-sectional side view of a second example implementation of contact structures, according to some aspects of the present disclosure.

FIG. 3A illustrates a cross-sectional side view of a semiconductor device, according to some examples.

FIG. 3B illustrates a cross-sectional side view of a semiconductor device having a plurality of contact structures, according to some aspects of the present disclosure.

FIG. 4A illustrates a cross-sectional side view of a 3D memory device, according to some examples.

FIG. 4B illustrates a cross-sectional side view of a 3D memory device having a plurality of contact structures, according to some aspects of the present disclosure.

FIG. 4C illustrates a cross-sectional side view of another 3D memory device having a plurality of contact structures, according to some aspects of the present disclosure.

FIG. 5 illustrates a cross-sectional side view of still another semiconductor device having a plurality of contact structures, according to some aspects of the present disclosure.

FIG. 6 illustrates a cross-sectional side view of yet another semiconductor device having a plurality of contact structures, according to some aspects of the present disclosure.

FIG. 7 is a flowchart of a method for forming a semiconductor device having a plurality of contact structures, according to some aspects of the present disclosure.

FIGS. 8A-8F illustrate a fabrication process for forming a semiconductor device having a plurality of contact structures, according to some aspects of the present disclosure.

FIG. 9 is a flowchart of a method for forming a plurality of contact structures in a semiconductor structure, according to some aspects of the present disclosure.

FIGS. 10A-10G illustrate a fabrication process for forming a plurality of contact structures in a semiconductor structure, according to some aspects of the present disclosure.

FIG. 11 illustrates a block diagram of an exemplary system having a 3D memory device, according to some aspects of the present disclosure.

FIG. 12A illustrates a diagram of an exemplary memory card having a 3D memory device, according to some aspects of the present disclosure.

FIG. 12B illustrates a diagram of an exemplary solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical contacts are formed) and one or more dielectric layers.

In some 3D memory devices, such as 3D NAND memory devices, channel structures are formed in a core array region. Memory cells for storing data are vertically stacked through a stack structure (e.g., a memory stack) in the vertical channel structures. 3D memory devices usually include staircase structures formed in staircase regions (e.g., on one or more sides (edges), or at the center, of the stacked storage structure) for purposes such as word line pick-up/fan-out using word line contacts landed onto different steps/levels of the staircase structures. Through substrate vias (TSVs) may also be formed on the edges or outside of the staircase regions to provide interconnection across the entire stack structure.

Initially, the stack structure may include interleaved first dielectric layers (e.g., silicon oxide layers) and second dielectric layers (e.g., silicon nitride layers). During the formation of the channel structures, all the second dielectric layers in the core array region and parts of the second dielectric layers in the staircase regions are replaced with conductive layers, leaving remainders of the second dielectric layers in the staircase regions. In some applications, the remainders of the second dielectric layers in the staircase regions need to be removed and then replaced by silicon oxide. The regions where the TSVs are located are also filled with silicon oxide. Then, the word line contacts and the TSVs can be formed by firstly etching the silicon oxide to form contact holes in the silicon oxide area and then filling the contact holes with conductive materials. However, with the removal of the remainders of the second dielectric layers in the staircase regions, the manufacturing process can be complicated and with high cost.

To address one or more of the aforementioned issues, the present disclosure introduces a solution that can form a plurality of contact structures in a connection region (a region outside of the core array region) without a need to remove the remainders of the second dielectric layers in the connection region. The plurality of contact structures formed thereof may include contact structures that only extend through a part of the stack structure, contact structures that extend through the whole stack structure and penetrate only a part of a semiconductor layer on which the stack structure is disposed, contact structures that extend through both the stack structure and the semiconductor layer, or any combination thereof. The contact structures that extend through both the stack structure and the semiconductor layer can be used as interconnect structures between stacked dies. Since the contact structures disclosed herein can be formed by etching the first dielectric layers and the remainders of the second dielectric layers, the manufacturing process can be simplified and at low cost.

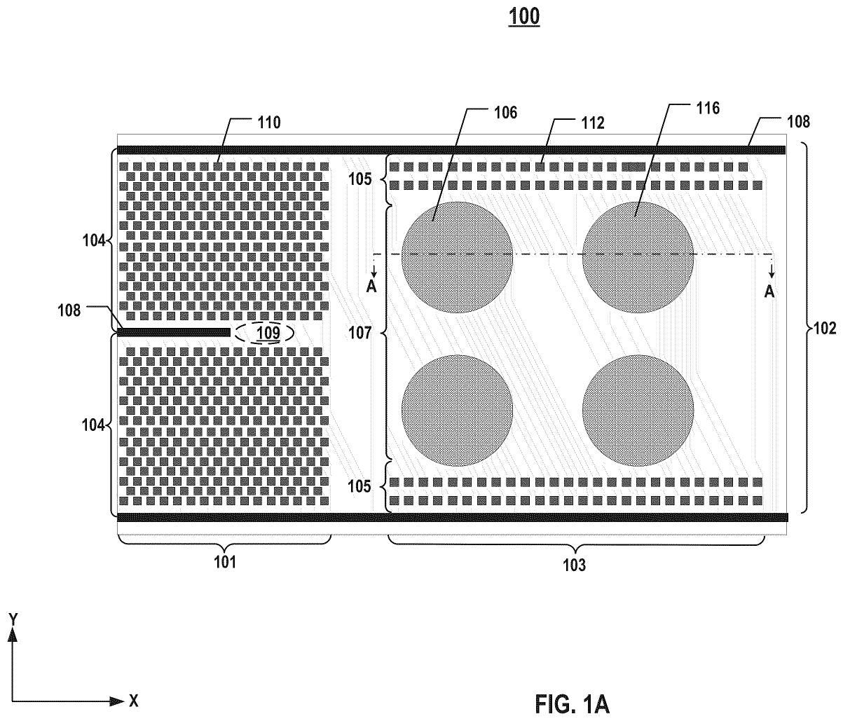

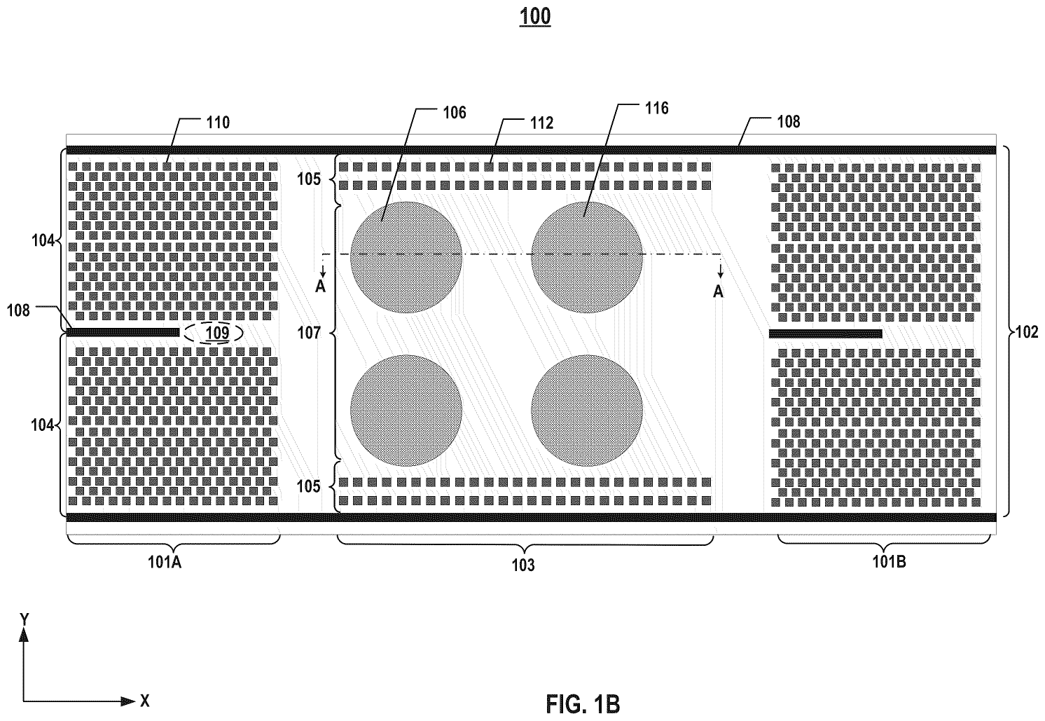

FIG. 1A illustrates a plan view of a semiconductor structure 100 having a plurality of contact structures, according to some aspects of the present disclosure. In some implementations, semiconductor structure 100 can be part of a NAND Flash memory device in which memory cells are provided in the form of an array of NAND memory strings. It is noted that x and y axes are included in FIG. 1A to illustrate two orthogonal (perpendicular) directions in the wafer plane. The x-direction is the word line direction of semiconductor structure 100, and the y-direction is the bit line direction of semiconductor structure 100.

As shown in FIG. 1A, semiconductor structure 100 can include one or more blocks 102 arranged in the y-direction (the bit line direction) separated by parallel slit structures 108, such as gate line slits (GLSs). In some implementations in which semiconductor structure 100 is a NAND Flash memory device, each block 102 is the smallest erasable unit of the NAND Flash memory device. Each block 102 can further include multiple fingers 104 in the y-direction separated by some of slit structures 108 with “H” cuts 109.

As shown in FIG. 1A, semiconductor structure 100 can be divided into at least a core array region 101 in which an array of channel structures 110 are formed, as well as a connection region 103 in which a plurality of contact structures 106, 116 are formed. Core array region 101 and connection region 103 are arranged in the x-direction (the word line direction), according to some implementations. It is understood that although one core array region 101 and one connection region 103 are illustrated in FIG. 1A, multiple core array regions 101 and/or multiple connection regions 103 may be included in semiconductor structure 100, for example, one connection region 103 between two core array regions 101 in the x-direction, or one core array region 101 between two connection regions 103. It is also understood that FIG. 1A only illustrates portions of core array region 101 that are adjacent to connection region 103.

As described below in detail, connection region 103 can include conductive portions 105 and dielectric portions 107 arranged in the y-direction. As shown in FIG. 1A, contact structures 106, 116 are disposed in dielectric portion 107, while dummy channel structures 112 are disposed in conductive portion 105 of connection region 103 to provide mechanical support and/or load balancing, according to some implementations. In some implementations (e.g., as shown in FIG. 1A), dummy channel structures 112 are disposed in dielectric portion 107 of connection region 103 as well, for example, between contact structures 106, 116 in the x-direction. In some implementations, dummy channel structures 112 are not disposed in dielectric portion 107 of connection region 103, i.e., only in conductive portion 105 of connection region 103. As shown in FIG. 1A, each finger 104 of semiconductor structure 100 can include one row of contact structures 106, 116 disposed in dielectric portion 107 of connection region 103. It is understood that the layout and arrangement of contact structures 106, 116, as well as the shape of each contact structure 106, 116 may vary in different examples.

FIG. 1B illustrates another plan view of semiconductor structure 100 having a plurality of contact structures, according to some aspects of the present disclosure. FIG. 1B may include components like those of FIG. 1A, and the similar description will not be repeated here. In FIG. 1B, core array region 101 may include a first part 101A and a second part 101B separated from first part 101A. Connection region 103 may connect first part 101A and second part 101B of core array region 101. For example, connection region 103 may be in the middle of first part 101A and second part 101B of core array region 101.

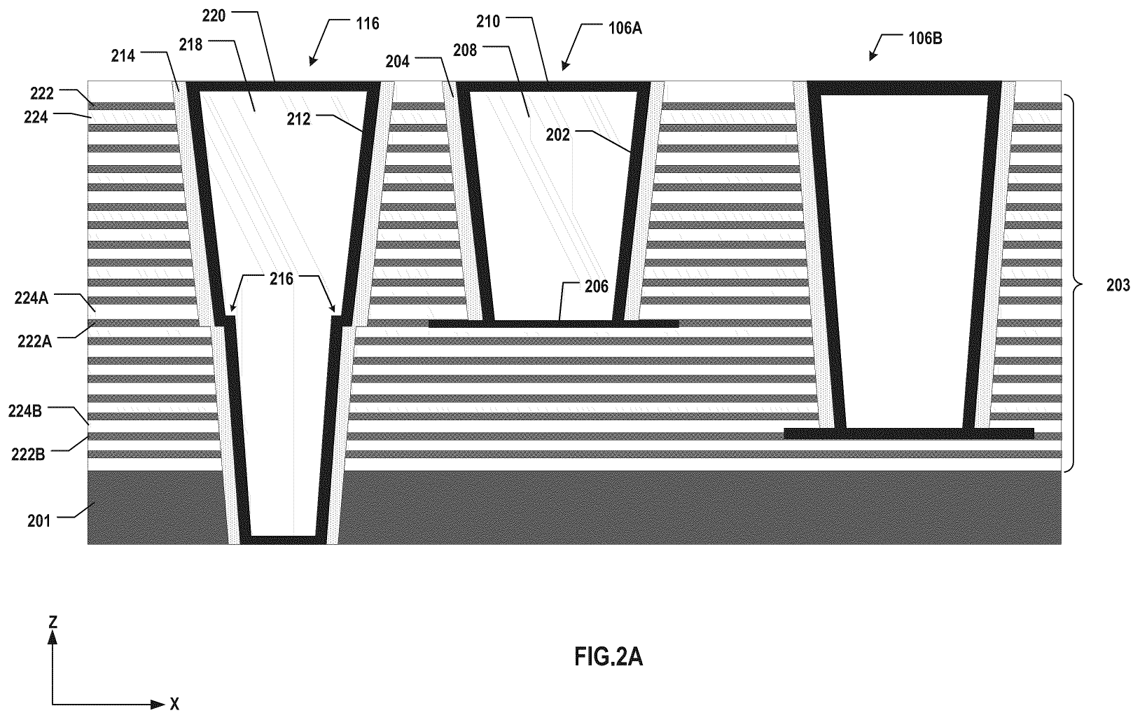

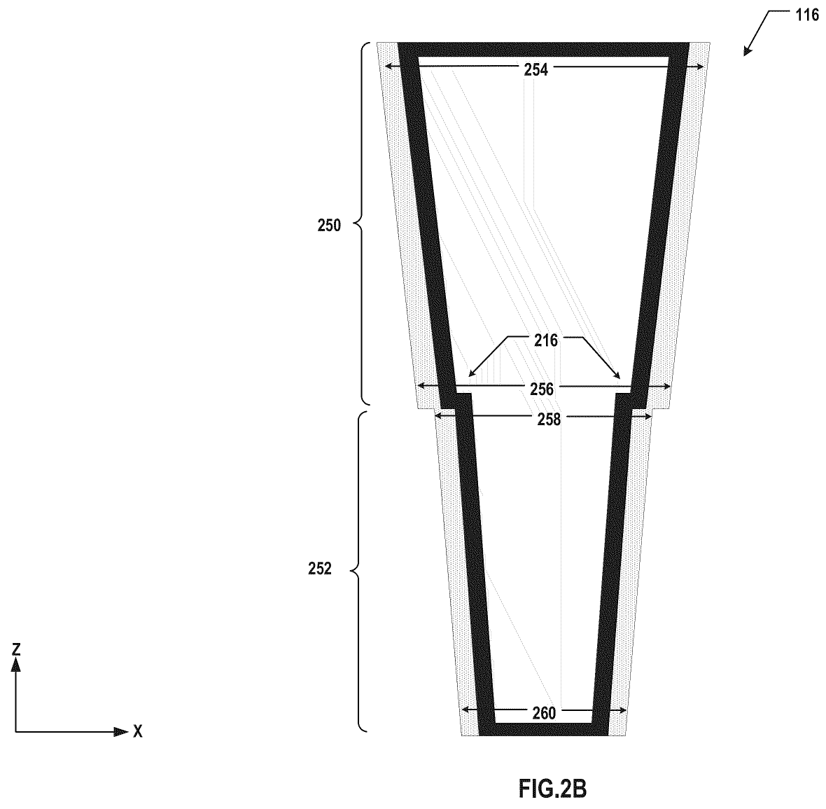

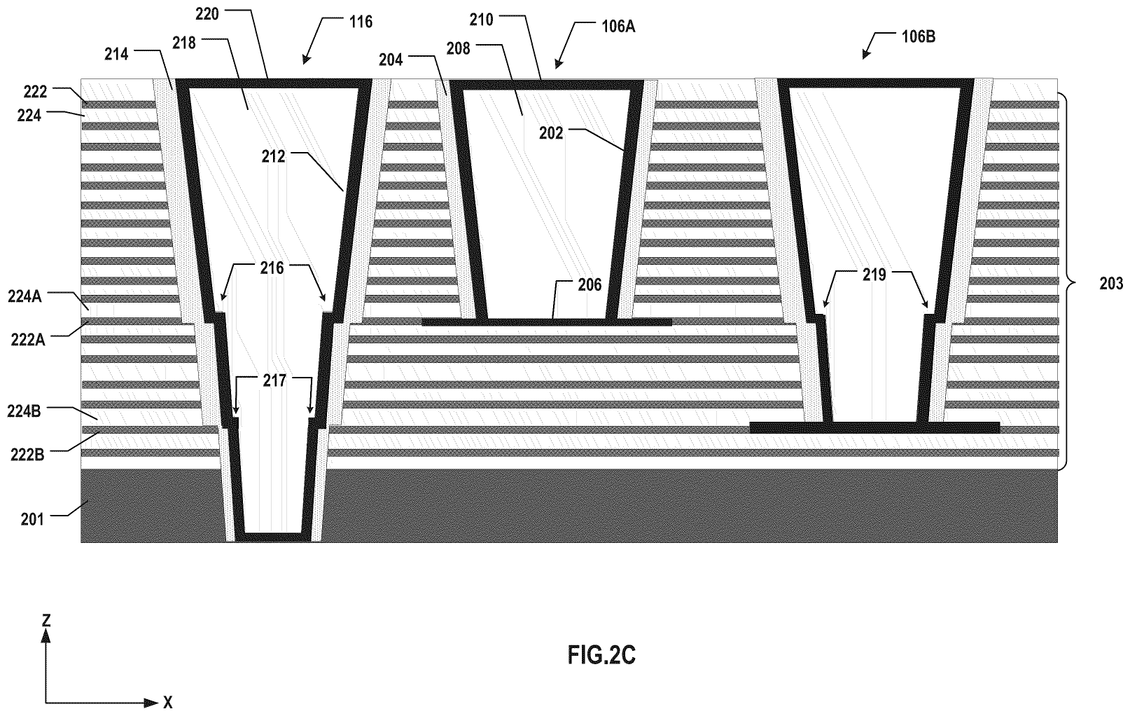

FIG. 2A illustrates a cross-sectional side view of a first example implementation of contact structures 106, 116, according to some aspects of the present disclosure. FIG. 2B illustrates a cross-sectional side view of a first contact structure 116 of FIG. 2A, according to some aspects of the present disclosure. FIGS. 2A and 2B are described together in more detail below. The cross-section may be along the AA direction in dielectric portion 107 of connection region 103 in FIG. 1A or 1B.

As shown in FIG. 2A, a stack structure 203 can be formed on a semiconductor layer 201. In some implementations, semiconductor layer 201 can be a substrate, which can include silicon (e.g., single crystalline silicon), silicon germanium (SiGe), gallium arsenide (GaAs), germanium (Ge), silicon on insulator (SOI), or any other suitable materials. In some implementations, the substrate includes single crystalline silicon, which is part of the wafer on which semiconductor structure 100 is fabricated, either in its native thickness or being thinned. In some implementations, the substrate includes, for example, polysilicon, which is a semiconductor layer replacing the part of wafer on which semiconductor structure 100 is fabricated. It is noted that x and z axes are included in FIG. 2A to further illustrate the spatial relationship of the components in semiconductor structure 100. Semiconductor layer 201 of semiconductor structure 100 includes two lateral surfaces extending laterally in the x-y plane: a top surface on the front side of the wafer on which stack structure 203 can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of semiconductor structure 100 is determined relative to semiconductor layer 201 of semiconductor structure 100 in the z-direction (the vertical direction perpendicular to the x-y plane). The same notion for describing the spatial relationship is applied throughout the present disclosure.

Stack structure 203 may include alternating first layers and first dielectric layers 224. The first layers and first dielectric layers 224 can alternate in the vertical direction (the z-direction). In some implementations, stack structure 203 can include a plurality of stack pairs which are stacked vertically in the z-direction, and each of the stack pairs includes one of the first layers and one of first dielectric layer 224.

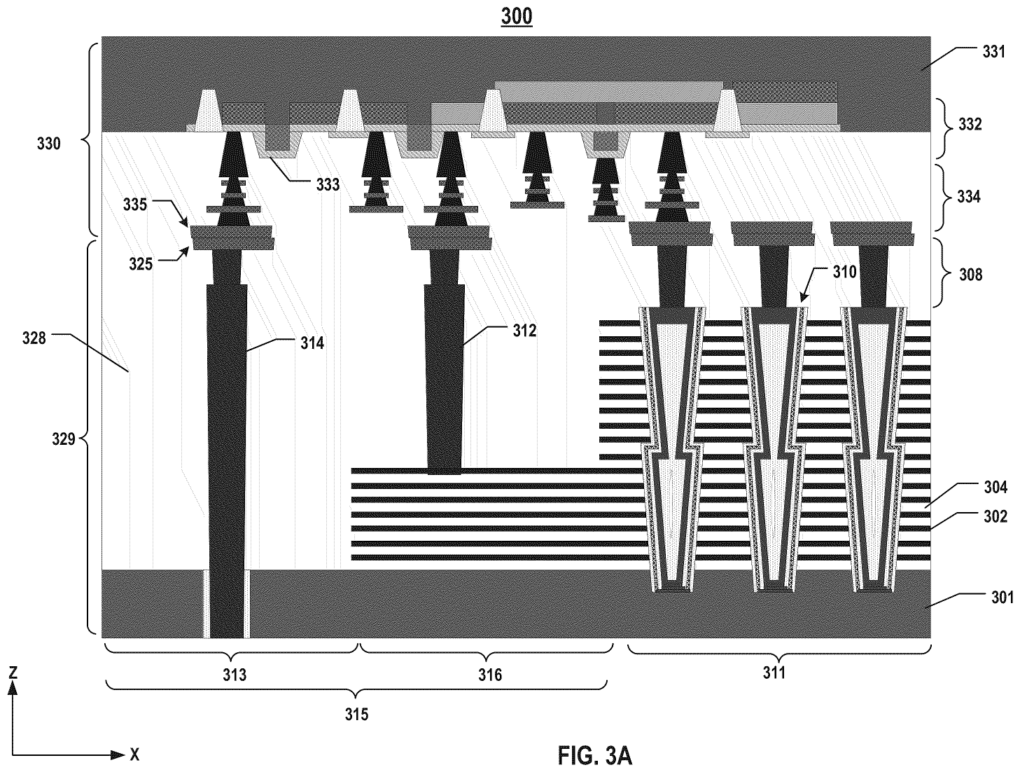

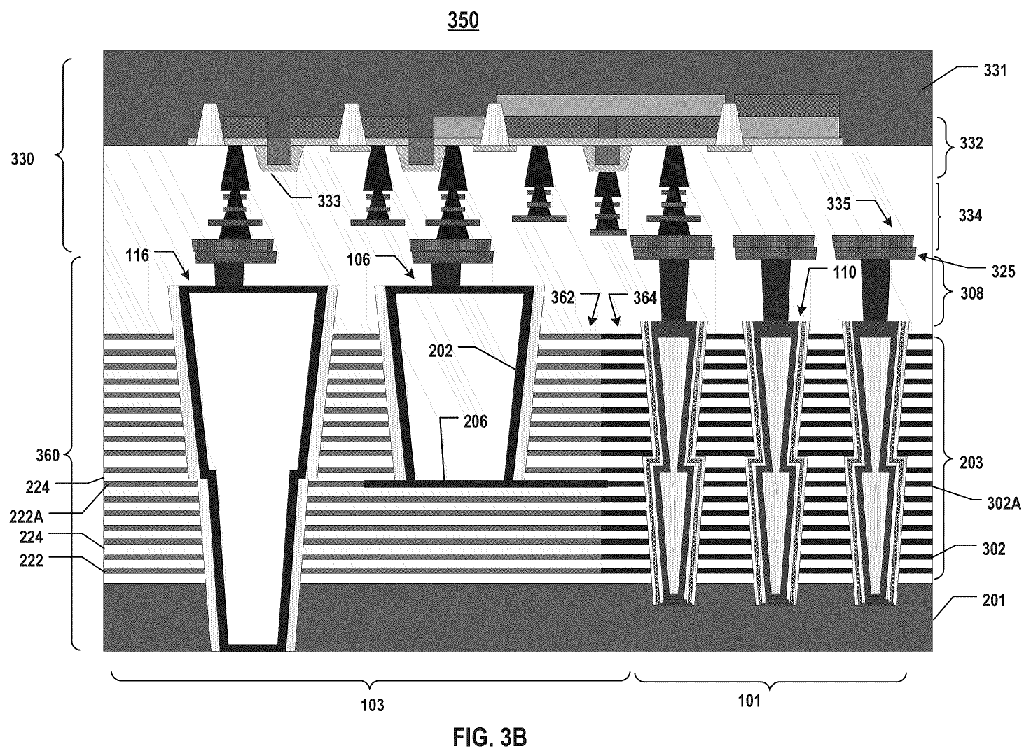

Stack structure 203 may include a first portion and a second portion adjacent to the first portion. The first portion can be in connection region 103. For example, with reference to FIG. 3B, the first portion and the second portion of stack structure 203 may be labeled with a first element 362 and a second element 364, respectively. Second portion 364 can include core array region 101 and a part of connection region 103, and first portion 362 may include a remaining portion of connection region 103. In a further example, the second portion may include core array region 101 and conductive portion 105 of connection region 103. The first portion may include dielectric portion 107 of connection region 103. By way of examples, FIG. 2A only shows the first portion of stack structure 203.

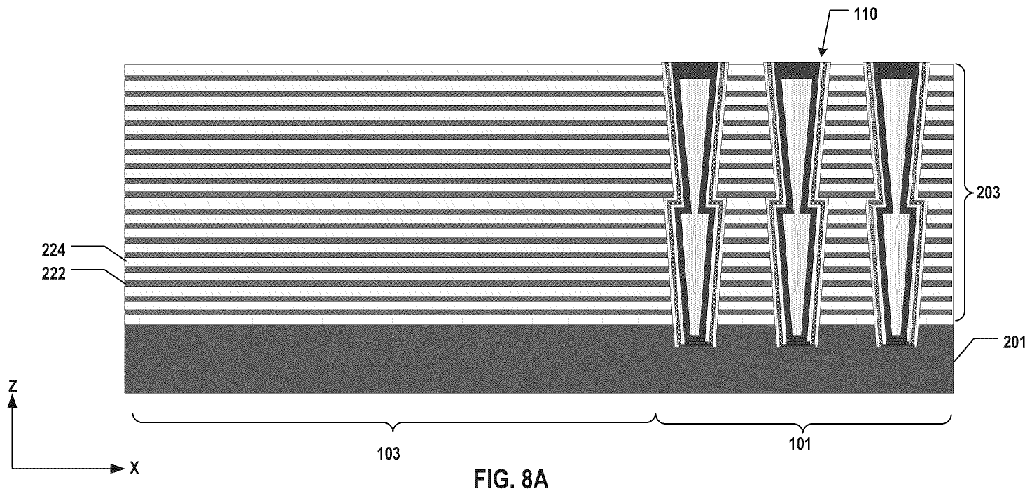

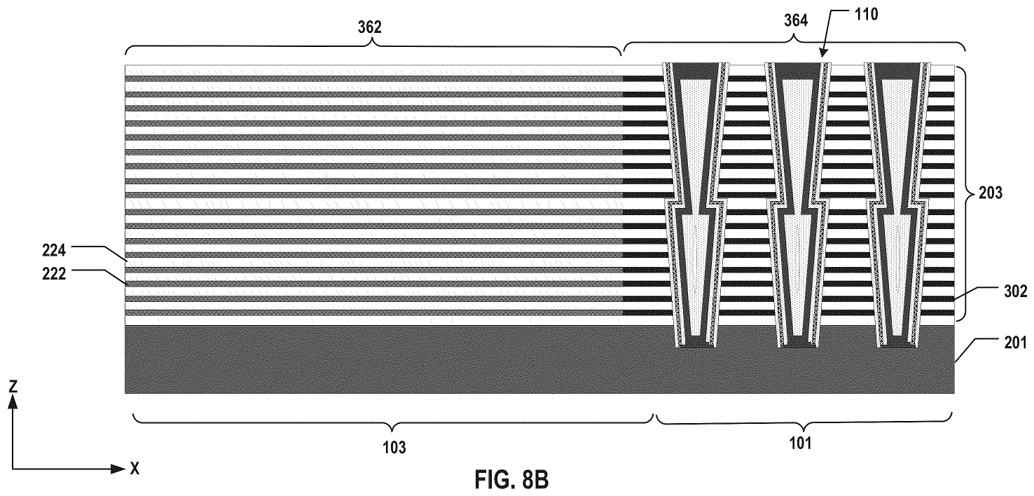

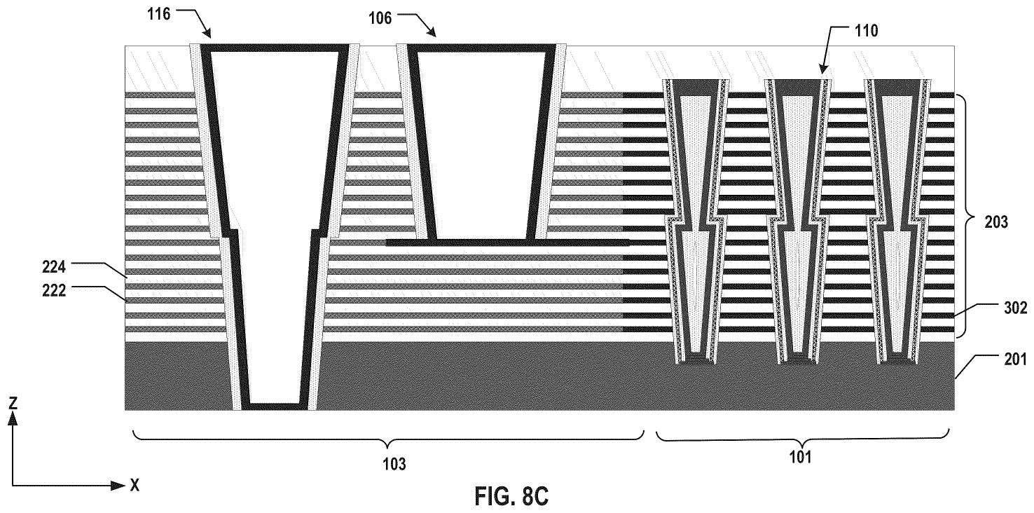

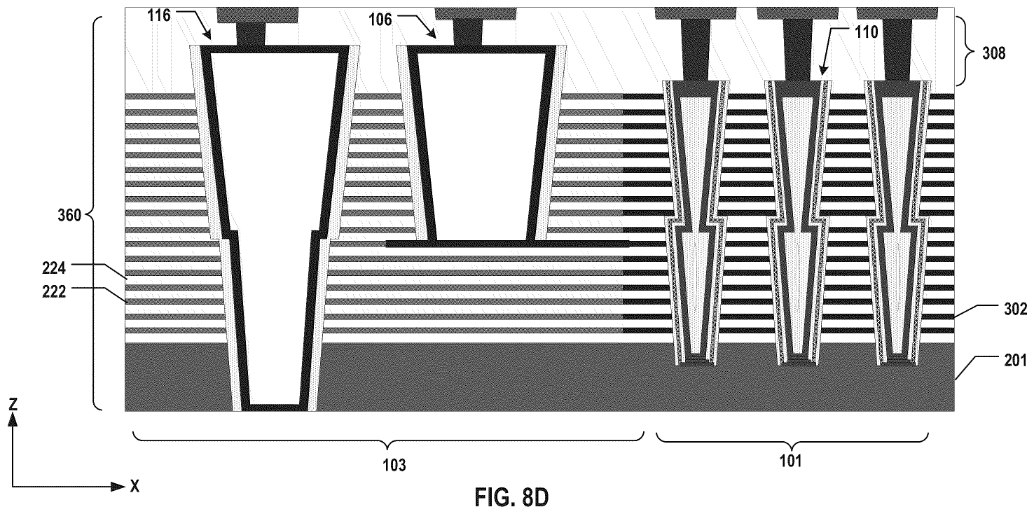

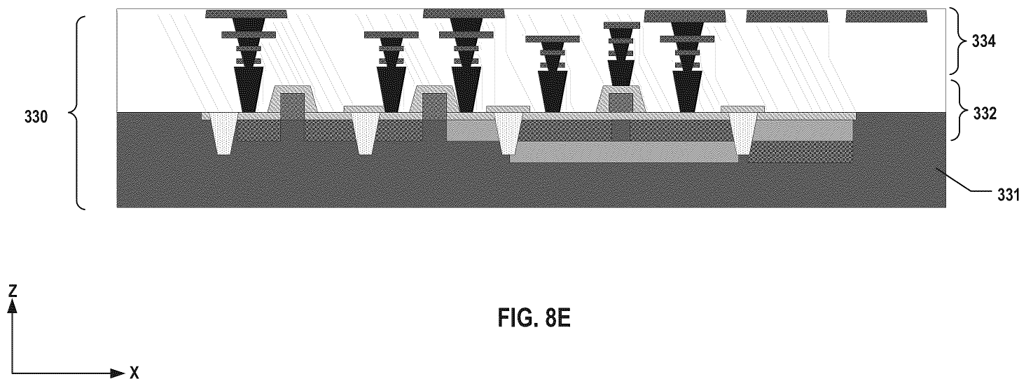

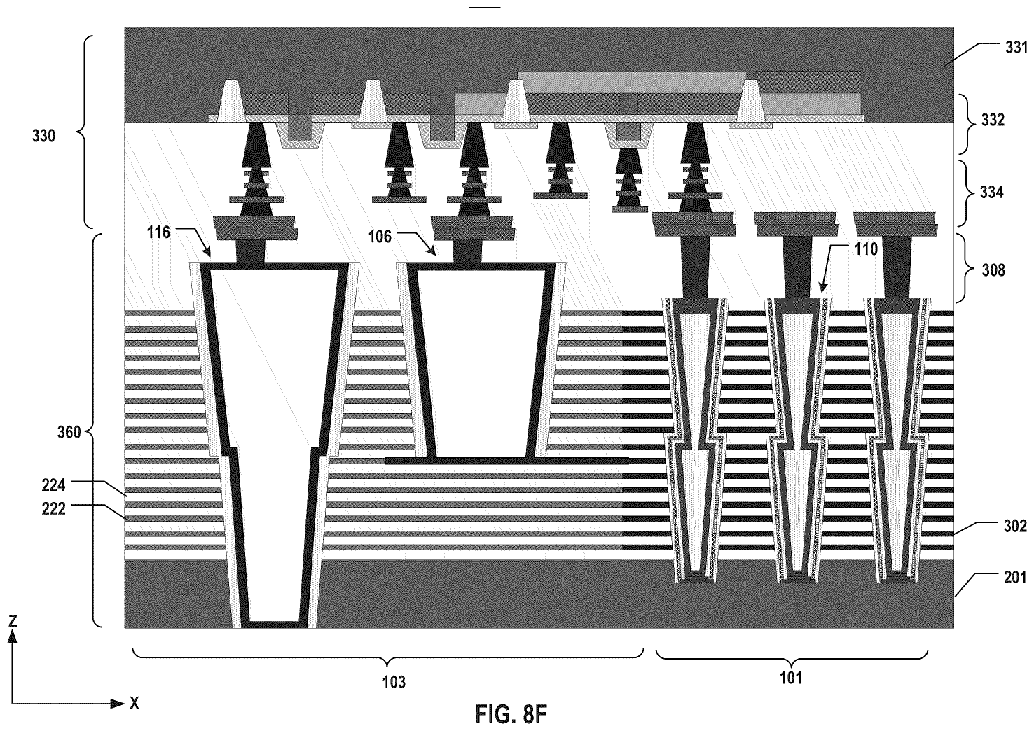

In some implementations, semiconductor structure 100 can be part of a NAND Flash memory device, and stack structure 203 can be a stacked storage structure through which NAND memory strings are formed. As shown in FIGS. 3B and 8B-8F below, the first layers of stack structure 203 can have different materials in different regions/portions of semiconductor structure 100. For example, the first layers in the first portion of stack structure 203 may include second dielectric layers 222. The first layers in the second portion of stack structure may include conductive layers 302. FIG. 2A shows the first portion of stack structure 203, which may include interleaved first dielectric layers 224 and second dielectric layers 222. As illustrated in FIGS. 3B and 8B-8F, the second portion of stack structure 203 may include interleaved first dielectric layers 224 and conductive layers 302.

As described below in detail with respect to a fabrication process of FIGS. 8A-8F, the formation of stack structure 203 with different materials of the first layers in different regions/portions can be achieved by controlling the different degrees and scopes of the gate replacement process in different regions/portions. For example, stack structure 203 may have undergone a complete gate replacement process in core array region 101 to replace all the second dielectric layers 222 with conductive layers 302, but a partial gate replacement process in connection region 103 to replace some of the second dielectric layers 222 with conductive layers 302 in a part of connection region 103, leaving the remainders of the second dielectric layers 222 in a remaining part of connection region 103.

In some implementations, each conductive layer in the second portion of stack structure 203 (within core array region 101 and conductive portion 105 of connection region 103) functions as a gate line of the NAND memory strings (in the forms of channel structures 110) in core array region 101, as well as a word line extending laterally from the gate line and ending in conductive portion 105 of connection region 103 for word line pick-up/fan-out through word line pick-up structures (e.g., contact structures 106). The word lines (i.e., the conductive layers) at different depths/level of the second portion of stack structure 203 each extend laterally in core array region 101 and conductive portion 105 of connection region 103, but are discontinuous (e.g., being replaced by the second dielectric layers 222) in dielectric portion 107 of connection region 103, according to some implementations.

Conductive layers 302 can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. First or second dielectric layers 222, 224 can include dielectric materials including, but not limited to, silicon oxide, silicon nitride, silicon oxynitride, or any combination thereof. First dielectric layers 224 and second dielectric layers 222 can have different dielectric materials, such as silicon oxide and silicon nitride, respectively. In some implementations, conductive layers 302 include metals, such as tungsten, first dielectric layers 224 include silicon oxide, and second dielectric layers 222 include silicon nitride.

By way of examples, FIG. 2A illustrates a first contact structure 116, a second contact structure 106A, and a third contact structure 106B. Second contact structure 106A and third contact structure 106B (referred to individually or collectively as 106) can be examples of word line pick-up structures. Second contact structure 106A and third contact structure 106B extend vertically into stack structure 203 (dielectric portion 107 of connection region 103) at different depths in the z-direction, according to some implementations. The top surfaces of second contact structure 106A and third contact structure 106B can be flush with one another, while the bottom surfaces of second contact structure 106A and third contact structure 106B can extend to different levels, for example, different second dielectric layers 222 of stack structure 203.

In some implementations, each of second contact structure 106A and third contact structure 106B includes a vertical contact structure (e.g., a conductor layer 202) and a lateral contact structure 206 connecting to the vertical contact structure. The vertical contact structure extends in the same direction as first contact structure 116. Lateral contact structure 206 connects with one of conductive layers 302. For example, each of second contact structure 106A and third contact structure 106B includes conductor layer 202, a spacer 204 circumscribing conductor layer 202, lateral contact structure 206 below and in contact with conductor layer 202. Conductor layer 202 and lateral contact structure 206 can include conductive materials including, but not limited to, W, Co, Cu, Al, TiN, polysilicon, doped silicon, silicides, or any combination thereof. Spacer 204 can include dielectric materials including, but not limited to, silicon oxide, silicon nitride, silicon oxynitride, or any combination thereof. In some implementations, conductor layer 202 and lateral contact structure 206 include TiN/W, and spacer 204 includes silicon oxide.

In some implementations, each of second contact structure 106A and third contact structure 106B may further include a filler body 208 surrounded by conductor layer 202. Filler body 208 can include dielectric materials including, but not limited to, silicon oxide, silicon nitride, silicon oxynitride, or any combination thereof. Each of second contact structure 106A and third contact structure 106B may further include a contact pad 210 on top of and in contact with filler body 208 and conductor layer 202. Contact pad 210 may be electrically connected to conductor layer 202. Contact pad 210 can include conductive materials including, but not limited to, W, Co, Cu, Al, TiN, polysilicon, doped silicon, silicides, or any combination thereof.

First contact structure 116 can be a contact structure which may extend through stack structure 203 and a part of or the entire semiconductor layer 201. For example, first contact structure 116 may penetrate stack structure 203 and a part of semiconductor layer 201. In another example, first contact structure 116 may penetrate both stack structure 203 and semiconductor layer 201, as illustrated in FIG. 2A.

Referring to FIG. 2B, first contact structure 116 may include a first segment 250 and a second segment 252 connected with first segment 250 in the z direction. First segment 250 can be located on a side of second segment 252 away from semiconductor layer 201. First segment 250 may include a first end 256 contacting second segment 252, and second segment 252 may include a second end 258 contacting first segment 250. A size of first end 256 can be greater than a size of second end 258 in the x direction perpendicular to the z direction. First segment 250 may further include a third end 254 away from first end 256, and second segment 252 may further include a fourth end 260 away from second end 258. A size of third end 254 can be greater than a size of first end 256 in the x direction, and a size of second end 258 can be greater than a size of fourth end 260 in the x direction.

Referring back to FIG. 2A, first contact structure 116 may include a conductor layer 212 and a spacer 214 surrounding conductor layer 212. First contact structure 116 may further include a filler body 218 surrounded by conductor layer 212, as well as a contact pad 220 on top of and in contact with filler body 218 and conductor layer 212. Contact pad 220 may be electrically connected to conductor layer 212. In some implementations, spacers 204 and 214 may include the same material or different materials, which is not limited herein. Conductor layers 202 and 212 may include the same material or different materials, which is not limited herein. Filler bodies 208 and 218 may include the same material or different materials, which is not limited herein.

In some implementations, the vertical contact structure (e.g., conductor layer 202) of second contact structure 106A may extend to a first stack pair. The first stack pair can be a pair including (a) one of first dielectric layers 224 and (b) one of the first layers in contact with the one of first dielectric layers 224. For example, as illustrated in FIG. 2A, the first stack pair may include a first dielectric layer 224A and a second dielectric layer 222A adjacent to first dielectric layer 224A. Lateral contact structure 206 of second contact structure 106A may be located in second dielectric layer 222A of the first stack pair. First contact structure 116 may include a first joint 216 in the first stack pair. As illustrated in FIG. 2B, first segment 250 and second segment 252 of first contact structure 116 may connect with one another at first joint 216.

In some implementations, the vertical contact structure (e.g., conductor layer 202) of third contact structure 106B may extend to a second stack pair, as illustrated in FIG. 2A. The second stack pair may include a first dielectric layer 224B and a second dielectric layer 222B adjacent to first dielectric layer 224B. Lateral contact structure 206 of third contact structure 106B may be located in second dielectric layer 222B of the second stack pair.

FIG. 2C illustrates a cross-sectional side view of a second example implementation of contact structures 106, 116, according to some aspects of the present disclosure. The cross-section may be along the AA direction in dielectric portion 107 of connection region 103 in FIG. 1A or 1B. FIG. 2C may include components like those of FIGS. 2A-2B, and the similar description will not be repeated herein. Compared with FIGS. 2A-2B, first contact structure 116 in FIG. 2C may include three segments, e.g., a first segment, a second segment, and a third segment from top to bottom. The first segment and the second segment connect with one another at first joint 216. The second segment and the third segment connect with one another at a second joint 217. Compared with FIG. 2A, third contact structure 106B may include two segments, e.g., a first segment on top and a second segment at the bottom of third contact structure 106B. The first and second segments of third contact structure 106B may connect with one another at a third joint 219.

The vertical contact structure (e.g., conductor layer 202) of second contact structure 106A may extend to the first stack pair (first dielectric layer 224A and second dielectric layer 222A). Lateral contact structure 206 of second contact structure 106A may be located in second dielectric layer 222A of the first stack pair. First joint 216 of first contact structure 116 and third joint 219 of third contact structure 106B may be in the first stack pair.

The vertical contact structure (e.g., conductor layer 202) of third contact structure 106B may extend to the second stack pair (first dielectric layer 224B and second dielectric layer 222B). Lateral contact structure 206 of third contact structure 106B may be located in second dielectric layer 222B of the second stack pair. Second joint 217 of first contact structure 116 may be in the second stack pair.

FIG. 3A illustrates a cross-sectional side view of a semiconductor device 300, according to some examples. Semiconductor device 300 may include a semiconductor structure 329 and a peripheral circuit 330 stacked on and connected with semiconductor structure 329. Peripheral circuit 330 can include a semiconductor layer 331 and a device layer 332 disposed on and in contact with semiconductor layer 331. In some implementations, device layer 332 includes one or more circuits such as driving circuits, page buffer circuits, and logic circuits. In some implementations, device layer 332 includes a plurality of transistors 333 in contact with semiconductor layer 331. Transistors 333 can include any transistors, such as Metal-Oxide Semiconductor (MOS) transistors, Complementary Metal-Oxide Semiconductor (CMOS) transistors, or transistors of other types.

In some implementations, peripheral circuit 330 may further include a connection layer 334 and a bonding layer 335. Connection layer 334 may be connected with device layer 332 to transfer electrical signals to and from device layer 332. As shown in FIG. 3A, connection layer 334 can be vertically between bonding layer 335 and device layer 332. Connection layer 334 can include a plurality of interconnects (also referred to herein as “contacts”), including lateral lines and vias. As used herein, the term “interconnects” can broadly include any suitable types of interconnects, such as middle-end-of-line (MEOL) interconnects and back-end-of-line (BEOL) interconnects. The interconnects in connection layer 334 can be coupled to transistors 333 in device layer 332. Connection layer 334 can further include one or more interlayer dielectric (ILD) layers (also known as “intermetal dielectric (IMD) layers”) in which the lateral lines and vias can form. That is, connection layer 334 can include lateral lines and vias in multiple ILD layers. In some implementations, the devices in device layer 332 are coupled to one another through the interconnects in connection layer 334. For example, different transistors 333 may be coupled to one another through connection layer 334. The interconnects in connection layer 334 can include conductive materials including, but not limited to, W, Co, Cu, Al, silicides, or any combination thereof. The ILD layers in connection layer 334 can include dielectric materials including, but not limited to, silicon oxide, silicon nitride, silicon oxynitride, low dielectric constant (low-k) dielectrics, or any combination thereof. In some implementations, the interconnects in connection layer 334 include W, which has a relatively high thermal budget (compatible with high-temperature processes) and good quality (fewer defects, e.g., voids) among conductive metal materials.

Semiconductor structure 329 may be divided into at least a core array region 311 and a connection region 315. Connection region 315 may also be divided into a staircase region 316 and a region 313 outside staircase region 316. In core array region 311, semiconductor structure 329 may include a semiconductor layer 301 and a stack structure formed on semiconductor layer 301. The stack structure may include interleaved conductive layers 302 and first dielectric layers 304. Semiconductor structure 329 may also include channel structures 310 extending through the stack structure. Memory cells for storing data are vertically stacked through the stack structure (e.g., a memory stack) in the vertical channel structures.

As shown in FIG. 3A, semiconductor structure 329 may also include a connection layer 308 formed on channel structures 310 and electrically connected with channel structures 310 to transfer electrical signals to and from memory cells formed in channel structures 310. In some implementations, connection layer 308 can include a plurality of interconnects, such as MEOL interconnects and BEOL interconnects. In some implementations, the interconnects in connection layer 308 also include local interconnects, such as bit line contacts and word line contacts. Connection layer 308 can further include one or more ILD layers in which the lateral lines and vias can form. The interconnects in connection layer 308 can include conductive materials including, but not limited to, W, Co, Cu, Al, silicides, or any combination thereof. The ILD layers in connection layer 308 can include dielectric materials including, but not limited to, silicon oxide, silicon nitride, silicon oxynitride, low-k dielectrics, or any combination thereof.

In staircase region 316, semiconductor structure 329 may include staircase structures. Semiconductor structure 329 may also include word line contacts 312 which extend through dielectric materials (e.g., nitride oxide) filled above the staircase structures and land onto different steps/levels of the staircase structures. In region 313 on the edge of or outside staircase region 316, semiconductor structure 329 may further include a TSV 314 which extends through both (a) dielectric materials (e.g., nitride oxide) filled in region 313 and (b) semiconductor layer 301.

As shown in FIG. 3A, semiconductor structure 329 may include a bonding layer 325 above and in contact with connection layer 308. In some implementations, semiconductor structure 329 and peripheral circuit 330 may be coupled to one another by hybrid bonding. Hybrid bonding (also known as “metal/dielectric hybrid bonding”) can be a direct bonding technology (e.g., forming bonding between surfaces without using intermediate layers, such as solder or adhesives) and can obtain metal-metal bonding and dielectric-dielectric bonding simultaneously. Hybrid bonding in a face-to-face manner can achieve millions of parallel short interconnects between the bonded semiconductor structures to increase the throughput and input/output (I/O) speed of the semiconductor packaging structure. Each of bonding layers 325, 335 can include a plurality of bonding contacts and dielectrics electrically isolating the bonding contacts. The bonding contacts can include conductive materials, such as Cu. The remaining area of each of bonding layers 325, 335 can be formed with dielectric materials, such as silicon oxide. The bonding contacts and surrounding dielectrics in each of bonding layers 325, 335 can be used for hybrid bonding.

A fabrication process of semiconductor structure 329 is described briefly herein. Initially, a stack structure including interleaved first dielectric layers 304 (e.g., silicon oxide layers) and second dielectric layers (e.g., silicon nitride layers) can be formed on semiconductor layer 301. Channel structures 310 may be formed to extend through the stack structure and into semiconductor layer 301. Then, all the second dielectric layers in core array region 311 and parts of the second dielectric layers in the staircase structures are replaced with conductive layers 302, leaving remainders of the second dielectric layers in staircase region 316. The remainders of the second dielectric layers in staircase region 316 can be removed and then replaced by silicon oxide. Region 313 is also filled with silicon oxide. As a result, a silicon oxide area 328 can be formed. Then, word line contact 312 in staircase region 316 and TSV 314 in region 313 can be formed by firstly forming contact holes in silicon oxide area 328 and then filling the contact holes with conductive materials. This fabrication process needs to remove the remainders of the second dielectric layers in staircase region 316, which can be complicated.

FIG. 3B illustrates a cross-sectional side view of a semiconductor device 350 having a plurality of contact structures 106, 116, according to some aspects of the present disclosure. Different from FIG. 3A, a plurality of contact structures 106, 116 can be formed in connection region 103 without a need to remove the remainders of second dielectric layers 222 in connection region 103, as described below in more detail. Thus, the fabrication process of semiconductor device 350 can be simplified. FIG. 3B may include components like those of FIGS. 1A-1B, 2A-2C, and 3A, and the similar description will not be repeated herein.

Semiconductor device 350 may include a semiconductor structure 360 and peripheral circuit 330 stacked on and connected with semiconductor structure 360. Semiconductor structure 360 may be divided into at least core array region 101 and connection region 103. In some implementations, semiconductor structure 360 may include semiconductor layer 201 and stack structure 203 over semiconductor layer 201. Stack structure 203 may include alternating first layers and first dielectric layers 224. Stack structure 203 may include a first portion 362 and a second portion 364 adjacent to first portion 362. In some examples, second portion 364 of stack structure 203 may include a first part in core array region 101A and a second part in core array region 101B separated from the first part (as illustrated in FIG. 1B), where first portion 362 of stack structure 203 connects the first part and the second part.

The first layers of first portion 362 may include second dielectric layers 222, whereas the first layers of second portion 364 may include conductive layers 302. For example, first portion 362 of stack structure 203 may include interleaved second dielectric layers 222 and first dielectric layers 224. Second portion 364 of stack structure 203 may include interleaved conductive layers 302 and first dielectric layers 224.

In some implementations, semiconductor structure 360 may further include (a) first contact structure 116 extending through first portion 362 and semiconductor layer 201 and (b) second contact structure 106 extending through a part of first portion 362 and connecting with one of conductive layers 302. For example, the vertical contact structure (e.g., conductor layer 202) of second contact structure 106 may extend to a first stack pair (e.g., a stack pair including first dielectric layer 224A and second dielectric layer 222A). Lateral contact structure 206 of second contact structure 106 may be located in second dielectric layer 222A and connect with a conductive layer 302A in the same layer (e.g., second dielectric layer 222A and conductive layer 302A are different parts of the same first layer).

Semiconductor structure 360 may further include channel structures 110 extending through second portion 364 into semiconductor layer 201. In the vertical direction (e.g., the z direction), a length of first contact structure 116 can be greater than a length of channel structures 110.

As shown in FIG. 3B, semiconductor structure 360 may also include connection layer 308 formed on channel structures 110 and electrically connected with channel structures 110 to transfer electrical signals to and from memory cells formed in channel structures 110. Connection layer 308 may also be connected with first contact structure 116 and second contact structure 106. As shown in FIG. 3B, semiconductor structure 360 may include bonding layer 325 above and in contact with connection layer 308. In some implementations, semiconductor structure 360 and peripheral circuit 330 may be coupled to one another by hybrid bonding. For example, connection layer 334 of peripheral circuit 330 can be bonded to connection layer 308 of semiconductor structure 360 using bonding layers 335 and 325. The bonding contacts and surrounding dielectrics in each of bonding layers 325, 335 can be used for hybrid bonding.

In some implementations, peripheral circuit 330 may be connected with first contact structure 116. In some implementations, peripheral circuit 330 may be disposed under stack structure 203, and first contact structure 116 may extend through semiconductor layer 301 to connect with peripheral circuit 330.

Consistent with some aspects of the present disclosure, instead of having staircase structures and word line contacts landed on different levels/stairs of the staircase structures, semiconductor structure 360 can include stack structure 203 with uniform heights (e.g., no staircase) and second contact structure 106 in dielectric portion 107 of connection region 103 for word line pick-up/fan-out. As shown in FIG. 3B, lateral contact structure 206 of each second contact structure 106 in dielectric portion 107 can extend laterally in the plane defined by x-direction and y-direction to be in contact with a corresponding conductive layer 302 (word line) in conductive portion 105 at the same level of stack structure 203. Since lateral contact structure 206 is in contact with conductor layer 202 of second contact structure 106, each second contact structure 106 is electrically connected to corresponding conductive layer 302 (word line) across conductive portion 105 in connection region 103 and core array region 101, according to some implementations. In other words, second contact structures 106 can extend vertically through stack structure 203 at different depths to be electrically connected to the word lines at different levels, respectively, to achieve word line pick-up/fan-out.

Consistent with some aspects of the present disclosure, first contact structure 116 and second contact structure 106 may be formed in the same region or different regions, which is not limited herein. For example, first contact structure 116 may be formed in a neighborhood of a sear ring, whereas second contact structure 106 may be formed in a region close to core array region 101. A semiconductor device disclosed herein may include: (a) a stack structure including alternating first and second dielectric layers; (b) a first contact structure 116 extending through the stack structure, and including a first conductor layer and a first spacer surrounding a sidewall of the first conductor layer; and (c) a second contact structure extending through a part of the stack structure, and including a second conductor layer and a second spacer surrounding a sidewall of the second conductor layer. The first spacer and the second spacer may include a first material (e.g., dielectric material), and the first conductor layer and the second conductor layer may include a second material (e.g., a conductive material) different from the first material.

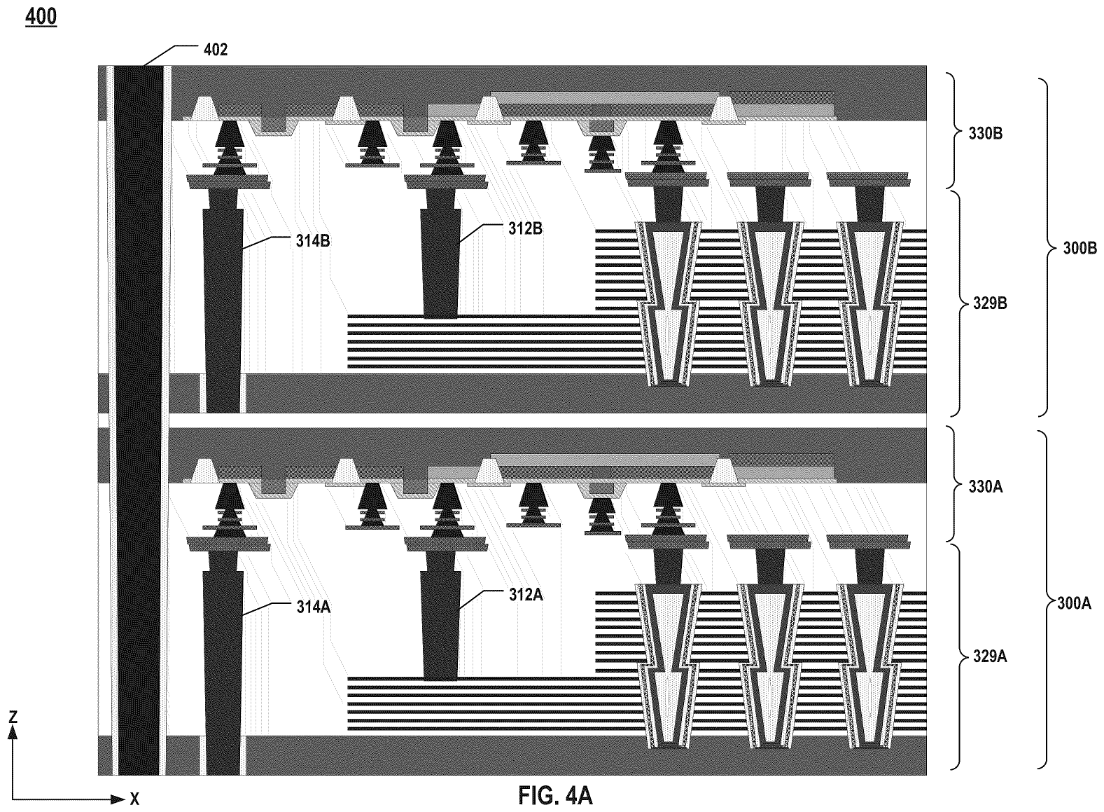

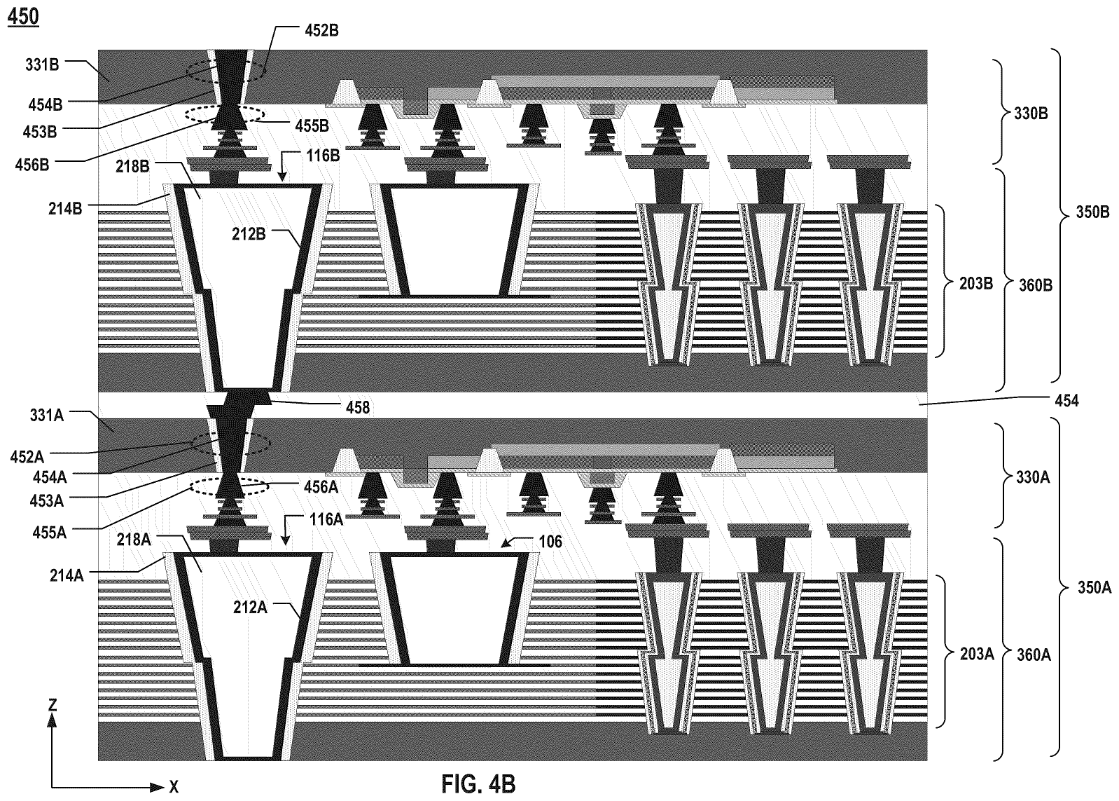

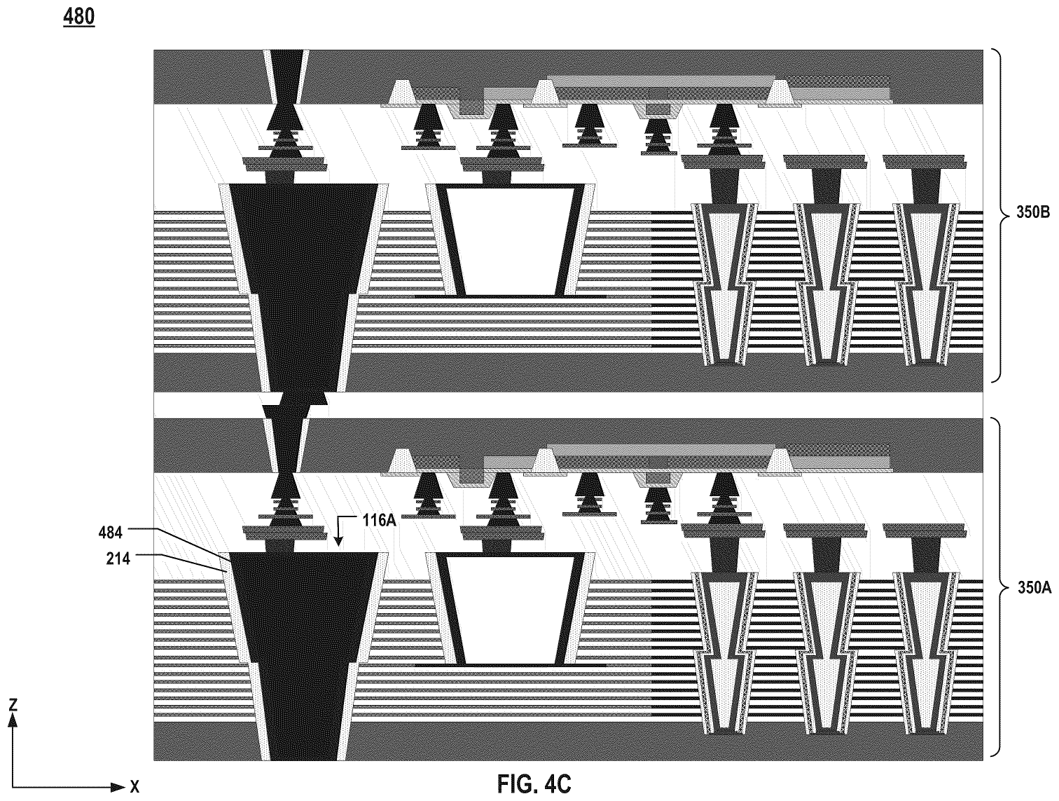

FIG. 4A illustrates a cross-sectional side view of a 3D memory device 400, according to some examples. Memory device 400 may include a first semiconductor device 300A and a second semiconductor device 300B. First and second semiconductor devices 300A, 300B may have structures like that of semiconductor device 300 of FIG. 3A, and the similar description will not be repeated herein. First and second semiconductor devices 300A, 300B may be bonded together to form memory device 400.

For example, first semiconductor device 300A may include a first semiconductor structure 329A and a first peripheral circuit 330A. First semiconductor structure 329A may include a word line contact 312A and a TSV 314A. Second semiconductor device 300B may include a second semiconductor structure 329B and a second peripheral circuit 330B. Second semiconductor structure 329B may include a word line contact 312B and a TSV 314B. It is contemplated that first and second semiconductor structures 329A, 329B may have structures like that of semiconductor structure 329 of FIG. 3A. First and second peripheral circuits 330A, 330B may have structures like that of peripheral circuit 330 of FIG. 3A. Word line contacts 312A, 312B may have structures like that of word line contact 312 of FIG. 3A. TSVs 314A, 314B may have structures like that of TSV 314 of FIG. 3A. The similar description will not be repeated herein.

As illustrated in FIG. 4A, memory device 400 may further include a through-die contact structure 402 which extends through both first and second semiconductor devices 300A, 300B. Besides TSVs 314A, 314B and word line contacts 312A, 312B, through-die contact structure 402 is additionally formed in memory device 400, which may require additional fabrication operations such as forming a via hole extending through both first and second semiconductor devices 300A, 300B, forming a spacer on a side wall of the via hole, and then filling the via hole with conductive materials to form a filler body. The formation of through-die contact structure 402 may make the fabrication process more complicated.

FIG. 4B illustrates a cross-sectional side view of a 3D memory device 450 having a plurality of contact structures 106, 116, according to some aspects of the present disclosure. Different from FIG. 4A, memory device 450 may utilize contact structures 116 to form through-die contact structures, and thus, there is no need to form additional through-die contact structure 402 like that of FIG. 4A. Thus, the fabrication process can be simplified.

Memory device 450 may include a first semiconductor device 350A and a second semiconductor device 350B. First and second semiconductor devices 350A, 350B may have structures like that of semiconductor device 350 of FIG. 3B, and the similar description will not be repeated herein. For example, first semiconductor device 350A may include a first semiconductor structure 360A and first peripheral circuit 330A. First semiconductor structure 360A may include a first stack structure 203A and channel structures 110A extending through first stack structure 203A. First semiconductor structure 360A may further include a first contact structure 116A, which may include a spacer 214A, a conductor layer 212A, and a filler body 218A. Second semiconductor device 350B may include a second semiconductor structure 360B and second peripheral circuit 330B. Second semiconductor structure 360B may include a second stack structure 203B and channel structures 110B extending through second stack structure 203B. Second semiconductor structure 360B may further include a first contact structure 116B, which may include a spacer 214B, a conductor layer 212B, and a filler body 218B. It is contemplated that first and second semiconductor structures 360A, 360B may have structures like that of semiconductor structure 360 of FIG. 3B. Stack structures 203A, 203B may have structures like that of stack structure 203 of FIGS. 2A-2B and 3B. First contact structures 116A, 116B may have structures like that of first contact structure 116 of FIGS. 2A-2B and 3B. The similar description will not be repeated herein.

First and second semiconductor devices 350A, 350B may be bonded together to form memory device 450. For example, a bonding layer 454 may be formed between first and second semiconductor devices 350A, 350B to bond the two devices together. Any suitable bonding technologies can be applied in bonding layer 454, such as hybrid bonding, anodic bonding, fusion bonding, transfer bonding, adhesive bonding, eutectic bonding, etc. An interconnect structure 458 can be formed in bonding layer 454, so that an interconnect structure 452A of first peripheral circuit 330A can be connected with first contact structure 116B of semiconductor structure 360B through interconnect structure 458.

Consistent with some aspects of the present disclosure, memory device 450 may include: (a) first semiconductor structure 360A including first stack structure and contact structure 116A extending through first stack structure 203A; (b) a second semiconductor structure 360B including second stack structure 203B and contact structure 116B extending through second stack structure 203B; and (c) first peripheral circuit 330A connected with contact structures 116A, 116B.

In some implementations, first stack structure 203A may include alternating first and second dielectric layers. Second stack structure 203B may include alternating third and four dielectric layers. The third and fourth dielectric layers may include the same materials as the first dielectric layers and the second dielectric layers, respectively.

In some implementations, first peripheral circuit 330A may be bonded with first semiconductor structure 360A, and first peripheral circuit 330A may include a first connect structure 455A between first semiconductor structure 360A and second semiconductor structure 360B. First connect structure 455A may be filled with a filler body 456A.

In some implementations, memory device 450 may further include second peripheral circuit 330B bonded with second semiconductor structure 360B. Second semiconductor structure 360B can be between first peripheral circuit 330A and second peripheral circuit 330B. Second peripheral circuit 330B may include a second connect structure 455B connecting contact structure 116B. Second connect structure 455B may be filled with a filler body 456B.

In some implementations, first peripheral circuit 330A may further include semiconductor layer 331A and an interconnect structure 452A extending through semiconductor layer 331A. Interconnect structure 452A may include a conductive filler 454A and a spacer 453A surrounding conductive filler 454A. Similarly, second peripheral circuit 330B may further include semiconductor layer 331B and an interconnect structure 452B extending through semiconductor layer 331B. Interconnect structure 452B may include a conductive filler 454B and a spacer 453B surrounding conductive filler 454B.

In some implementations, first contact structure 116A may include an insulating filler (e.g., filler body 218A) and conductor layer 212A surrounding insulating filler, whereas interconnect structure 452A may include conductive filler 454A and spacer 453A surrounding conductive filler 454A. Conductor layer 212A of first contact structure 116A can be connected with conductive filler 454A of interconnect structure 452A. Similarly, second contact structure 116B may include an insulating filler (e.g., filler body 218B) and conductor layer 212B surrounding insulating filler, whereas interconnect structure 452B may include conductive filler 454B and spacer 453B surrounding conductive filler 454B. Conductor layer 212B of second contact structure 116B can be connected with conductive filler 454B of interconnect structure 452B.

Consistent with some aspects of the present disclosure, a memory device disclosed herein may include: (a) a first contact structure (e.g., 116A) including an insulating filler and a conductor layer surrounding the insulating filler and extending in a first direction such as the z direction; and (b) a second contact structure (e.g., 452A) including a conductive filler and a spacer surrounding a sidewall of the conductive filler and extending in the first direction. The conductor layer connects with the conductive filler.

FIG. 4C illustrates a cross-sectional side view of another 3D memory device 480 having a plurality of contact structures, according to some aspects of the present disclosure. Memory device 480 may have components like those of memory device 450 of FIG. 4B, and the similar description will not be repeated herein. First contact structures 116 in FIG. 4C may have structures different from those of FIG. 4B. Specifically, in FIG. 4C, each first contact structure 116 may include a conductive filler body and a spacer surrounding the conductive filler body. The conductive filler body may include any conductive material disclosed herein. For example, as shown in FIG. 4C, first contact structure 116A of first semiconductor device 350A may include a conductive filler body 484 and spacer 214 surrounding conductive filler body 484.

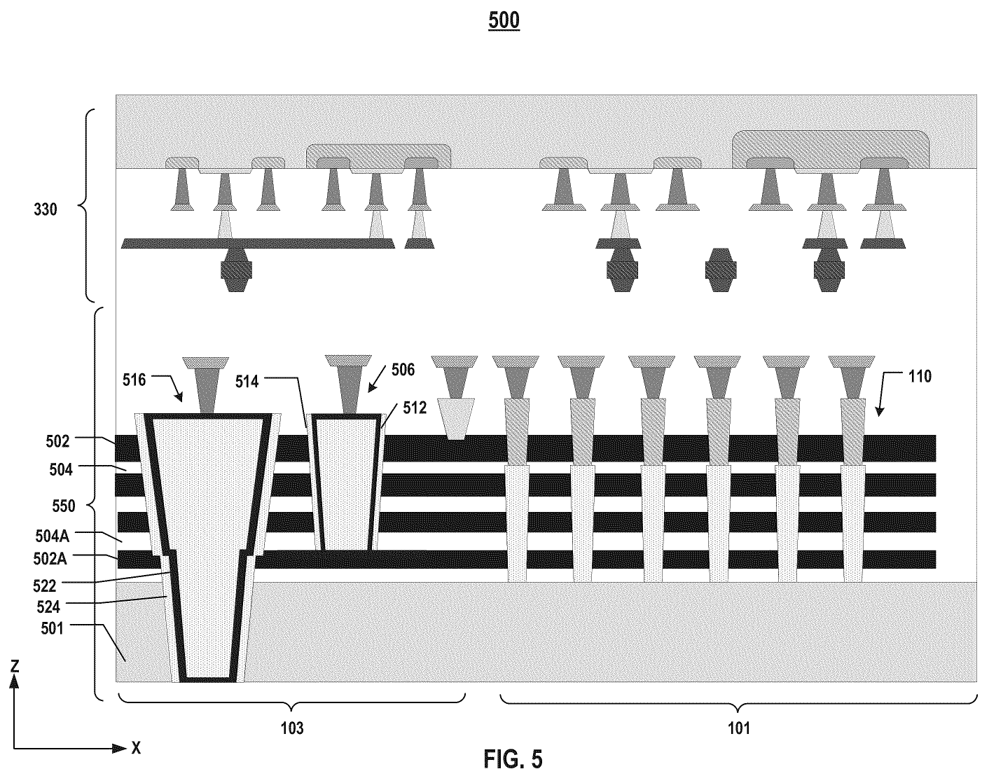

FIG. 5 illustrates a cross-sectional side view of still another semiconductor device 500 having a plurality of contact structures, according to some aspects of the present disclosure. Semiconductor device 500 may include a semiconductor structure 550 and peripheral circuit 330. Semiconductor structure 550 may include a semiconductor layer 501, a stack structure over semiconductor layer 501 and including alternating conductive layers 502 and dielectric layers 504, channel structures 110 extending through the stack structure, a first contact structure 516 extending through the stack structure, and a second contact structure 506 extending through a portion of the stack structure. First contact structure 516 may include a first conductor layer 522 and a first spacer 524 surrounding a sidewall of first conductor layer 522. Second contact structure 506 may include a second conductor layer 512 and a second spacer 514 surrounding a sidewall of second conductor layer 512. Second conductor layer 512 connects with one of conductive layers 502 (such as a conductive layer 502A), and first conductor layer 522 and conductive layers 302 are separated by first spacer 524.

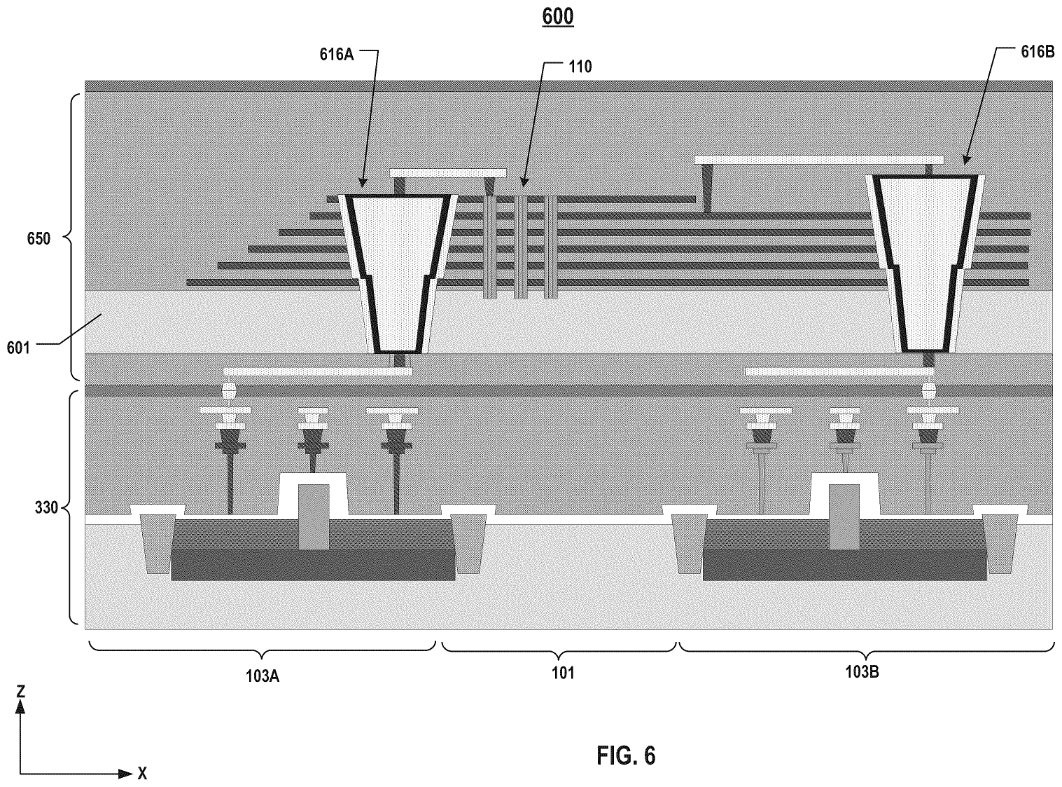

It is contemplated that first contact structure 516 may have a structure like that of first contact structure 116 of FIGS. 2A-2C, 3B, and 4B, and second contact structure 506 may have a structure like that of second contact structure 106 of FIGS. 2A-2C, 3B, and 4B. However, first contact structure 516 and second contact structure 506 of FIG. 5 extend through alternating conductive layers 502 and dielectric layers 504, whereas first contact structure 116 and second contact structure 106 of FIGS. 2A-2C, 3B, and 4B extend through alternating first dielectric layers 224 and second dielectric layers 222. Second contact structure 506 of FIG. 5 has no lateral contact structure. Second contact structure 506 may extend to a stack pair including conductive layer 502A and a dielectric layer 504A, and first contact structure 516 may have a joint in the stack pair. FIG. 6 illustrates a cross-sectional side view of yet another semiconductor device 600 having a plurality of contact structures, according to some aspects of the present disclosure. Semiconductor device 600 may include a semiconductor structure 650 and peripheral circuit 330. Semiconductor structure 650 may include a semiconductor layer 601, a stack structure over semiconductor layer 601 and including alternating conductive layers and dielectric layers, channel structures 110 extending through the stack structure, and contact structures 616A, 616B extending through the stack structure and semiconductor layer 601. Contact structures 616A and 616B are in connection regions 103A and 103B, respectively. In some implementations, peripheral circuit 330 may be disposed under the stack structure, and contact structures 616A, 616B may extend through semiconductor layer 601 to connect with peripheral circuit 330.

It is contemplated that contact structures 616A, 616B may have a structure like that of first contact structure 116 of FIGS. 2A-2C, 3B, and 4B. However, contact structures 616A, 616B extend through alternating conductive layers and dielectric layers, whereas first contact structure 116 of FIGS. 2A-2C, 3B, and 4B extend through alternating first dielectric layers 224 and second dielectric layers 222.

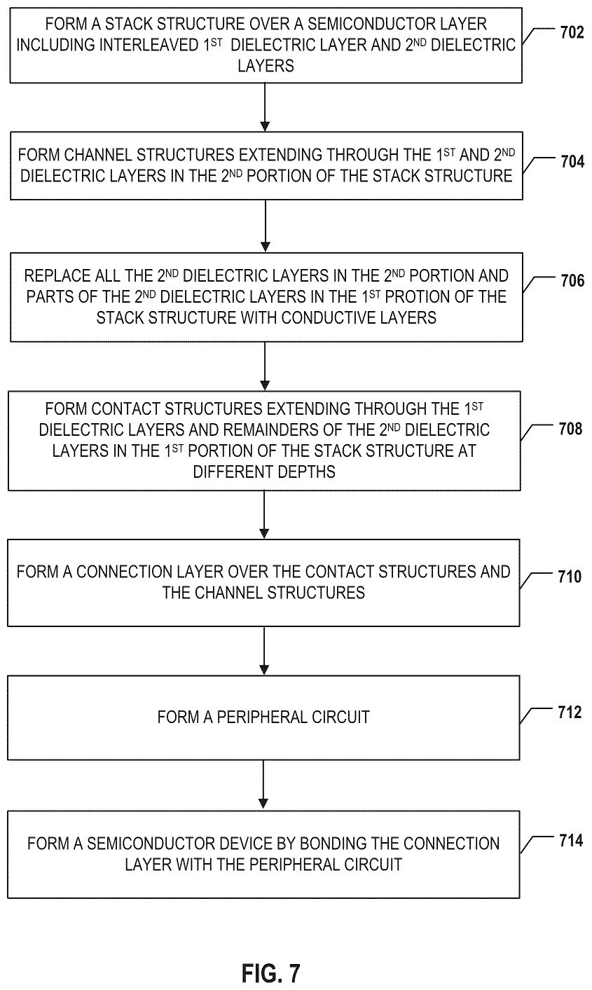

FIG. 7 is a flowchart of a method 700 for forming a semiconductor device having a plurality of contact structures, according to some aspects of the present disclosure. FIGS. 8A-8F illustrate a fabrication process for forming a semiconductor device having a plurality of contact structures, according to some aspects of the present disclosure. Examples of the semiconductor device depicted in FIGS. 7 and 8A-8F include semiconductor device 350 depicted in FIG. 3B. FIGS. 7 and 8A-8F will be described together. It is understood that the operations shown in method 700 are not exhaustive and that other operations can be performed as well before, after, or between any of the illustrated operations. Further, some of the operations may be performed simultaneously, or in a different order than that shown in FIG. 7.

Referring to FIG. 7, method 700 starts at operation 702, in which a stack structure including interleaved first dielectric layers and second dielectric layers is formed on a semiconductor layer. The first dielectric layers can include silicon oxide, and the second dielectric layers can include silicon nitride. The stack structure can be formed by one or more thin film deposition processes including, but not limited to, ALD, CVD, PVD, or any combination thereof.

Method 700 proceeds to operation 704, as illustrated in FIG. 7, in which channel structures extending through the first dielectric layers and the second dielectric layers are formed in the core array region of the stack structure. For example, with reference to FIG. 8A, stack structure 203 including interleaved first dielectric layers 224 and second dielectric layers 222 can be formed over semiconductor layer 201. Channel structures 110 can be formed to extend through stack structure 203 into semiconductor layer 201.

In some implementations, to form a channel structure, a channel hole extending vertically through the stack structure is formed, and a memory layer and a channel layer are sequentially formed over sidewalls of the channel hole. In some implementations, to form the channel structure, a channel hole extending vertically through the stack structure is formed, and a high-k gate dielectric layer, a memory layer, and a channel layer are sequentially formed over sidewalls of the channel hole. In some implementations, dummy channel structures (e.g., dummy channel structures 112 in FIG. 1A) extending through the first dielectric layers and the second dielectric layers are formed in the second region of the stack structure in the same process of forming the channel structures. That is, channel structures and dummy channel structures can be simultaneously formed through the first dielectric layers and the second dielectric layers in the first portion and the second portion of the stack structure, respectively.

In some implementations, to form channel structures, a plurality of channel holes are opened, such that each channel hole becomes the location for growing an individual channel structure in the later process. In some implementations, fabrication processes for forming channel holes of channel structures include wet etching and/or dry etching, such as deep-ion reactive etching (DRIE). Subsequently, a memory layer (including a blocking layer, a storage layer, and a tunneling layer) and a channel layer are sequentially formed in this order along sidewalls and the bottom surface of the channel hole. In some implementations, the memory layer is first deposited along the sidewalls and bottom surface of the channel hole, and the semiconductor channel is then deposited over the memory layer. The blocking layer, storage layer, and tunneling layer can be subsequently deposited in this order using one or more thin film deposition processes, such as ALD, CVD, PVD, any other suitable processes, or any combination thereof, to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (a “SONO” structure) are subsequently deposited to form the memory layer and the channel layer of the channel structure.

In some implementations, a high-k gate dielectric layer is formed before the formation of the memory layer. That is, the high-k gate dielectric layer, memory layer (including the blocking layer, storage layer, and tunneling layer), and the channel layer can be sequentially formed in this order along sidewalls and the bottom surface of the channel hole. In some implementations, the high-k gate dielectric layer is first deposited along the sidewalls and bottom surfaces of the channel hole, the memory layer is then deposited over the high-k gate dielectric layer, and the semiconductor channel is then deposited over the memory layer. The high-k gate dielectric layer can be formed by depositing high-k dielectric materials, such as aluminum oxide, using one or more thin film deposition processes, such as ALD, CVD, PVD, any other suitable processes, or any combination thereof. The blocking layer, storage layer, and tunneling layer can be subsequently deposited in this order using one or more thin film deposition processes, such as ALD, CVD, PVD, any other suitable processes, or any combination thereof, over the high-k gate dielectric layer to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, an aluminum oxide layer, a first silicon oxide layer, a silicon nitride layer, a second silicon oxide layer, and a polysilicon layer (a “SONO” structure) are subsequently deposited to form the high-k gate dielectric layer, the memory layer, and the channel layer of the channel structure.

In some implementations, dummy channel structures (e.g., dummy structures 112 in FIGS. 1A and 1B) can be formed in a connection region (e.g., connection region 103 in FIGS. 1A-1B and 3B) of the stack structure (e.g., stack structure 203 in FIGS. 2A, 2C, and 3B), in the same process of forming the channel structures. To form each dummy channel structure, a dummy channel hole, which is another opening extending vertically through the stack structure, can be formed in the connection region simultaneously as the channel hole by the same wet etching and/or dry etching, such as DRIE. The dummy channel structure can then be formed simultaneously as the channel structure by the same thin film deposition processes, such as ALD, CVD, PVD, any other suitable processes, or any combination thereof that deposit a memory layer (including a blocking layer, a storage layer, and a tunneling layer) and a channel layer, or a high-k gate dielectric layer, a memory layer (including a blocking layer, a storage layer, and a tunneling layer), and a channel layer. It is understood that in some examples, the dummy channel structures may be formed in a separate process from the channel structures.

Method 700 proceeds to operation 706, as illustrated in FIG. 7, in which all the second dielectric layers in the second portion and parts of the second dielectric layers in the first portion of the stack structure are replaced with conductive layers, for example, by a gate replacement process. The conductive layer can include a metal. For example, with reference to FIG. 8B, stack structure 203 may include first portion 362 and second portion 364. All the second dielectric layers 222 in second portion 364 (including core array region 101 and a part of connection region 103) are replaced with conductive layers 302, for example, by a gate replacement process.

At the beginning of the gate replacement process, a slit extending through first dielectric layers 224 and second dielectric layers 222 and across first and second portions 362, 364 of stack structure 203 is formed. In some implementations, the slit extends vertically through the local contact layer as well. The slit can also extend laterally across core array region 101 and connection region 103 in the x-direction (the word line direction). In some implementations, fabrication processes for forming the slit include wet etching and/or dry etching, such as DRIE, of the first dielectric layers and the second dielectric layers. The etching process through the stack structure may not stop at the top surface of the silicon substrate and may continue to etch part of the silicon substrate to ensure that the slit extends vertically all the way through all the first dielectric layers and second dielectric layers of stack structure 203.

Thereafter, the part of the slit in the core array region is covered by a sacrificial layer. In some implementations, the sacrificial layer that is different from the first dielectric layers and the second dielectric layers, such as a polysilicon layer or a carbon layer, is deposited into the slit using one or more thin film deposition processes, such as CVD, PVD, ALD, or any combination thereof, to at least partially fill the slit (covering the exposed first dielectric layers and second dielectric layers in the slit). The sacrificial layer can then be patterned using lithography and wet etching and/or dry etching to remove the part of the sacrificial layer in the connection region, leaving only the part of the sacrificial layer in the core array region to cover only the part of the slit in the core array region.

Subsequently, parts of the second dielectric layers 222 in the connection region 103 of the stack structure 203 are removed through the slit in the connection region 103 of the stack structure 203. The removal can be performed by wet etching to form lateral recesses, leaving the remainders of second dielectric layers 222 in a dielectric portion of the connection region 103 intact. In some implementations, the parts of the second dielectric layers are wet etched by applying a wet etchant through the part of the slit in the connection region that is uncovered by the sacrificial layer, creating lateral recesses interleaved between the first dielectric layers 224. The wet etchant can include phosphoric acid for etching the second dielectric layers including silicon nitride. In some implementations, one or both of the etching rate and etching time are controlled to remove only the parts of the second dielectric layers 222 in the conductive portion (e.g., conductive portion 105 in FIGS. 1A-1B), leaving the remainders of the second dielectric layers 222 intact in the dielectric portion (e.g., dielectric portion 107 in FIGS. 1A-1B). By controlling the etching time, the wet etchant does not travel all the way to completely remove the second dielectric layers in connection region 103, thereby defining two portions in the connection region—the dielectric portion in which the second dielectric layers are removed, and the dielectric portion in which the second dielectric layers remain. Since the part of the slit in core array region 101 is covered by the sacrificial layer that is resistant to the etchant for removing the second dielectric layers, all the second dielectric layers remain intact in core array region 101.

Then, the slit in core array region 101 of the stack structure is opened. Specifically, the part of the slit in core array region 101 is re-opened by removing the sacrificial layer to expose the first dielectric layers and the second dielectric layers. In some implementations, the sacrificial layer is selectively etched away from the part of the slit in the core array region, for example, using potassium hydroxide (KOH) for etching the sacrificial layer having polysilicon, to open the part of the slit in the core array region.

After that, the slit in connection region 103 of the stack structure is covered. Specifically, the lateral recesses and the part of the slit in the connection region are covered by another sacrificial layer. In some implementations, the sacrificial layer that is different from the first dielectric layers and the second dielectric layers, such as a polysilicon layer or a carbon layer, is deposited into the lateral recesses and the slit using one or more thin film deposition processes, such as ALD, CVD, PVD, or any combination thereof, to at least partially fill the slit (covering the exposed first dielectric layers and second dielectric layers). The sacrificial layer can then be patterned using lithography and wet etching and/or dry etching to remove the part of the sacrificial layer in the core array region, leaving only the part of the sacrificial layer in the connection region to cover only the lateral recesses and the part of the slit in the connection region, but not in the core array region. It is understood that the lateral recesses may be considered as parts of the slit in the connection region. Thus, even if only the lateral recesses are fully or partially filled by the sacrificial layer, the part of the slit in the connection region may still be considered as being covered.

Later, all the second dielectric layers in core array region 101 of the stack structure are removed through the slit in core array region 101 of the stack structure. Specifically, all the second dielectric layers in core array region 101 are fully removed by wet etching to form lateral recesses. In some implementations, the second dielectric layers are wet etched by applying a wet etchant through the part of the slit in the core array region that is uncovered by the sacrificial layer, creating the lateral recesses interleaved between the first dielectric layers. The wet etchant can include phosphoric acid for etching the second dielectric layers including silicon nitride. In some implementations, one or both of the etching rate and etching time are controlled to ensure that all the second dielectric layers in the core array region are completely etched away. Since the part of the slit in the connection region 103 is covered by the sacrificial layer that is resistant to the etchant for removing the second dielectric layers, the remainders of the second dielectric layers in the dielectric portion 107 of the connection region 103 remain intact.

Afterward, the slit in the connection region of the stack structure is opened. Specifically, the part of the slit in the connection region is re-opened by removing the sacrificial layer to expose the first dielectric layers and the remainders of the second dielectric layers in the connection region. In some implementations, the sacrificial layer is selectively etched away from the part of the slit in the connection region, for example, using KOH for etching the sacrificial layer having polysilicon, to open the part of the slit (and the lateral recesses) in the connection region.

Finally, the conductive layers are deposited into lateral recesses in core array region 101 and conductive portion 105 of connection region 103 through the slit. In some implementations in which high-k gate dielectric layers are not formed in the channel structures, the high-k gate dielectric layers are deposited into the lateral recesses prior to the conductive layers, such that the conductive layers are deposited on and surrounded by the high-k gate dielectric layers. In some implementations in which high-k gate dielectric layers are formed in the channel structures, the high-k gate dielectric layers are not deposited into the lateral recesses prior to the conductive layers, such that the conductive layers are deposited on and surrounded by the first dielectric layers. The conductive layers, such as metal layers, can be deposited using one or more thin film deposition processes, such as ALD, CVD, PVD, any other suitable processes, or any combination thereof.

As described above, the removal of the second dielectric layers (stack sacrificial layers, e.g., having silicon nitride) can be performed separately in the core array region and the connection region by partially covering the slit in the core array region or the connection region to allow the second dielectric layers to be removed at different scopes (e.g., fully removal in the core array region and partial removal in the connection region). It is understood that in another gate replace process, the removal of the second dielectric layers may be performed first in the core array region, and then in the connection region.

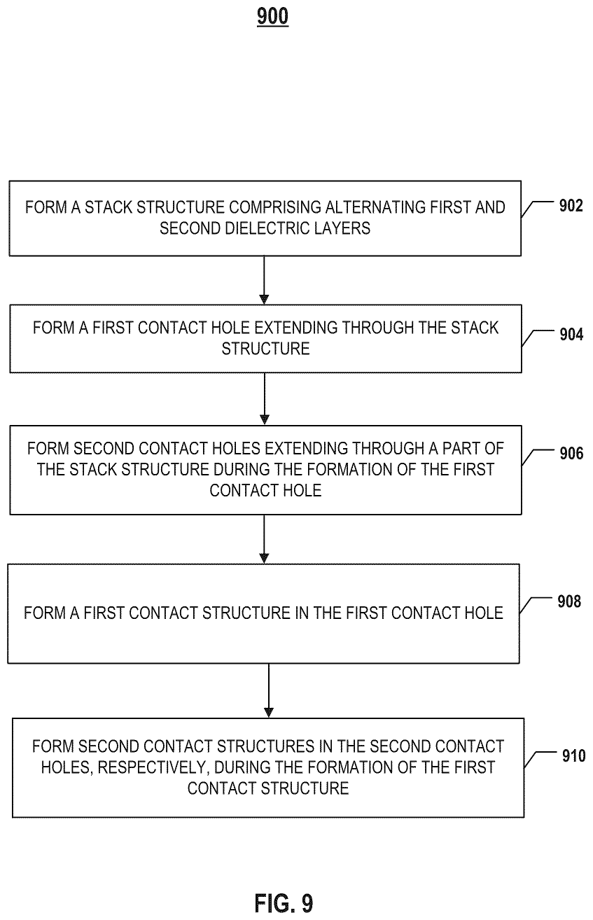

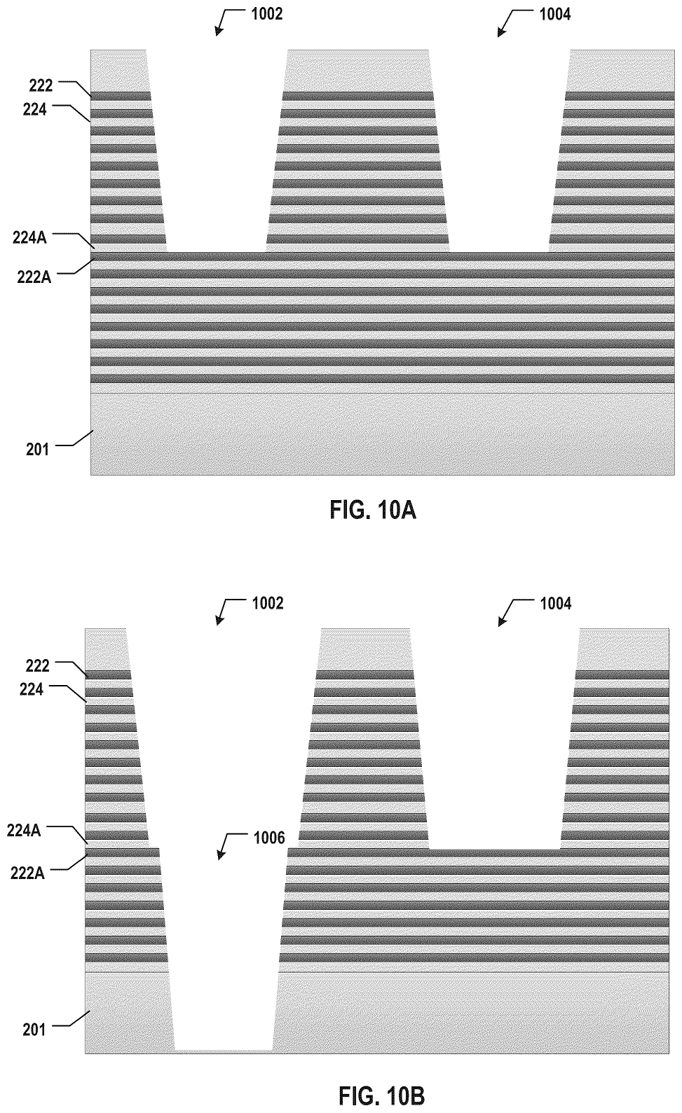

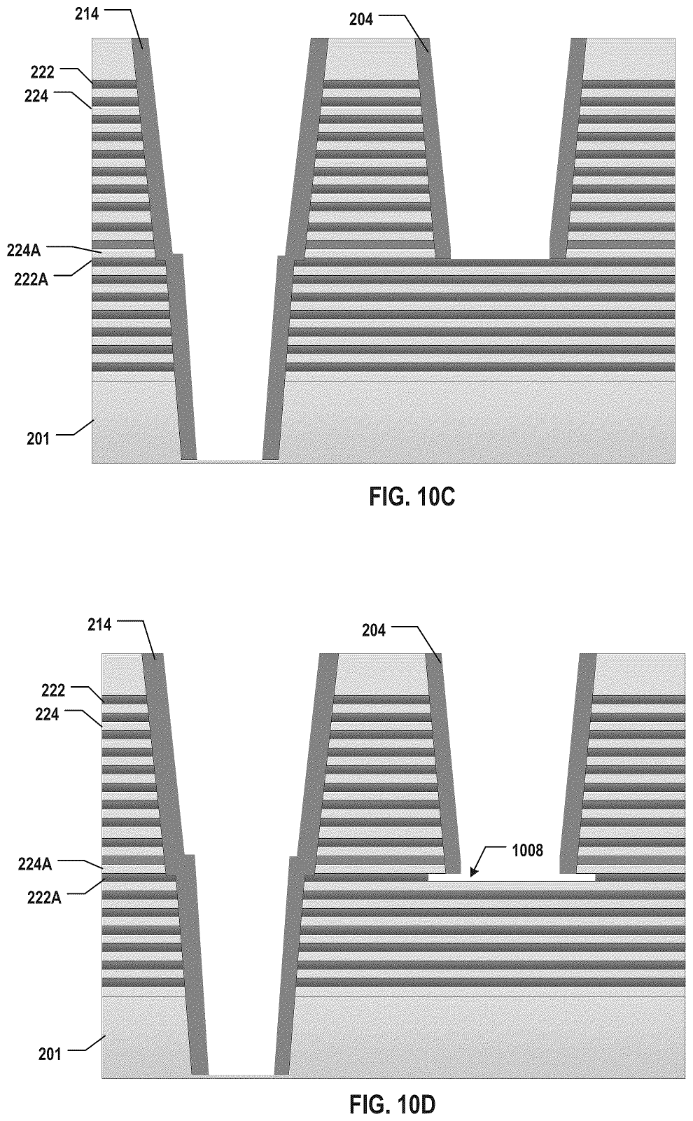

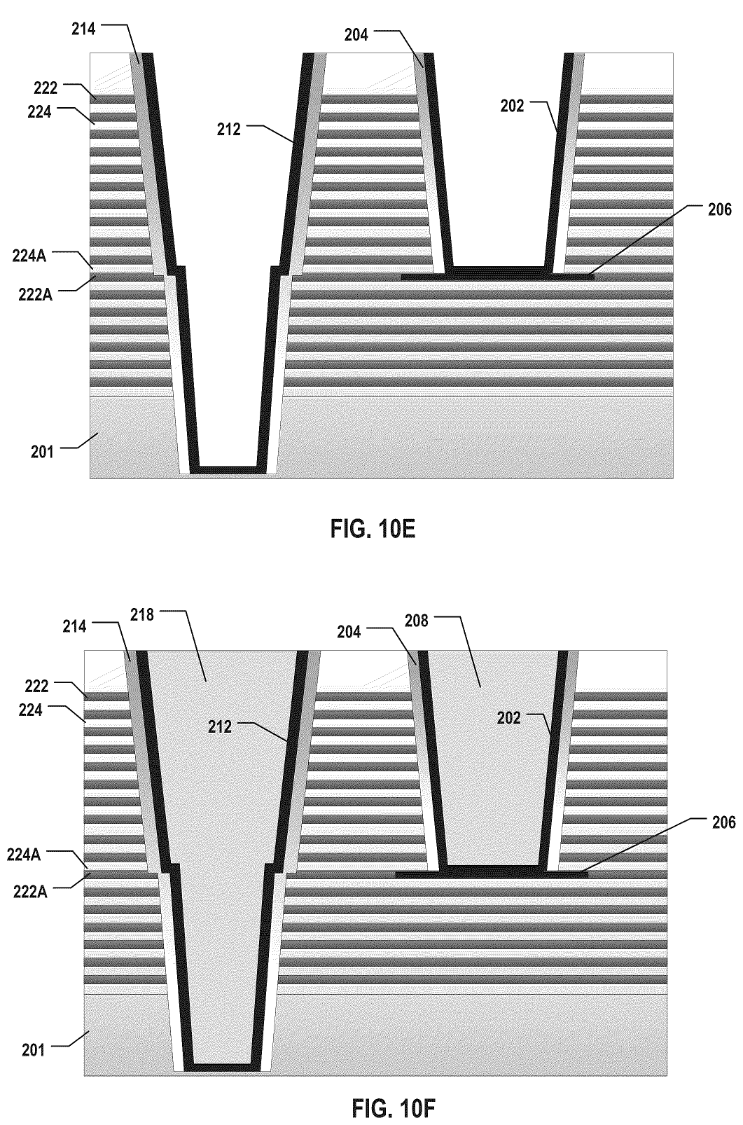

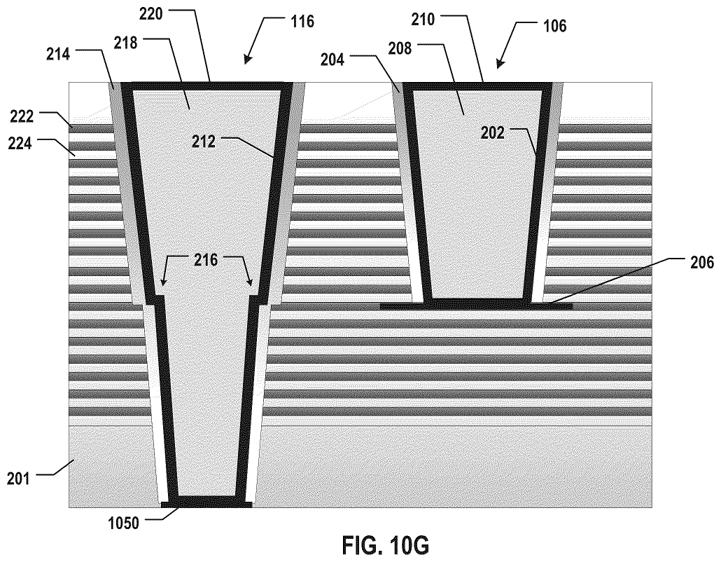

Referring back to FIG. 7, method 700 proceeds to operation 708, as illustrated in FIG. 7, in which contact structures extending through the first dielectric layers and remainders of the second dielectric layers in the first portion of the stack structure are formed at different depths. For example, with reference to FIG. 8C, first contact structure 116 extending through first dielectric layers 224 and remainders of second dielectric layers 222, as well as second contact structure 106 extending through a part of first dielectric layers 224 and remainders of second dielectric layers 222, may be formed in connection region 103. An example method and an example fabrication process to form the contact structures are illustrated below with reference to FIGS. 9 and 10A-10G, respectively.

Referring back to FIG. 7, method 700 proceeds to operation 710, as illustrated in FIG. 7, in which a connection layer is formed over the contact structures and the channel structures. For example, with reference to FIG. 8D, connection layer 308 may be formed over contact structures 116, 106 and channel structures 110. As a result, semiconductor structure 360 can be formed.

Referring back to FIG. 7, method 700 proceeds to operation 712, as illustrated in FIG. 7, in which a peripheral circuit is formed. For example, with reference to FIG. 8E, peripheral circuit 330 may be formed by forming device layer 332 over semiconductor layer 331 and connection layer 334 over device layer 332.

Referring back to FIG. 7, method 700 proceeds to operation 714, as illustrated in FIG. 7, in which a semiconductor device is formed by bonding the connection layer with the peripheral circuit. For example, with reference to FIG. 8F, peripheral circuit 330 of FIG. 8C may be flipped over and bonded to connection layer 308 of semiconductor structure 360 to form semiconductor device 350 of FIG. 3B.

FIG. 9 is a flowchart of a method 900 for forming a plurality of contact structures in a semiconductor structure, according to some aspects of the present disclosure. FIGS. 10A-10G illustrate a fabrication process for forming a plurality of contact structures in a semiconductor structure, according to some aspects of the present disclosure. Examples of the semiconductor structure depicted in FIGS. 9 and 10A-10G include semiconductor structure 360 depicted in FIG. 3B. FIGS. 9 and 10A-10G will be described together. It is understood that the operations shown in method 900 are not exhaustive and that other operations can be performed as well before, after, or between any of the illustrated operations. Further, some of the operations may be performed simultaneously, or in a different order than that shown in FIG. 9.

Referring to FIG. 9, method 900 starts at operation 902, in which a stack structure including interleaved (or alternating) first dielectric layers and second dielectric layers is formed on a semiconductor layer. The first dielectric layers can include silicon oxide, and the second dielectric layers can include silicon nitride. The stack structure can be formed by one or more thin film deposition processes including, but not limited to, ALD, CVD, PVD, or any combination thereof.

Method 900 proceeds to operation 904, as illustrated in FIG. 9, in which a first contact hole extending through the stack structure is formed. Method 900 proceeds to operation 906, as illustrated in FIG. 9, in which second contact holes extending through a part of the stack structure during the formation of the first contact hole are formed.

For example, with reference to FIG. 10A, a stack structure including interleaved first dielectric layers 224 and second dielectric layers 222 is formed on semiconductor layer 201. The stack structure may be etched with a first mask to form a first opening 1002 and a second opening 1004 which extends into the stack structure. In some implementations, second opening 1004 may form at least one of the second contact holes. First and second openings 1002, 1004 may have the same depth and extend into a first stack pair including first dielectric layer 224A and second dielectric layer 222A to expose second dielectric layer 222A. Although only one second opening 1004 is shown in FIG. 10A, a plurality of second openings 1004 may be formed, which is not limited herein.

With reference to FIG. 10B, first opening 1002 may be etched with a second mask to form a third opening 1006 which extends further through the stack structure and semiconductor layer 201. Thus, the first contact hole is formed which includes first opening 1002 and third opening 1006. It is noted that a small remainder portion of semiconductor layer 201 may not be etched away when forming third opening 1006, so that materials of a first contact structure formed in the first contact hole may be deposited above the remainder portion of semiconductor layer 201. This remainder portion of semiconductor layer 201 may be removed after the first contact structure is formed, as illustrated below in FIG. 10G.

In some implementations, the stack structure may be further etched with a third mask to form a fourth opening (not shown in the figures) which extends into the stack structure with a depth different from that of opening 1004. The second contact holes may further include the fourth opening. For example, the fourth opening may form a second contact hole for second contact structure 106B of FIG. 2A. By performing similar operations, a plurality of second contact holes extending into the stack structure with identical or different depths can be formed by etching the stack structure with identical or different masks.

The method forming openings with different depths is known as a chopping process. As used herein, a “chopping” process is a process that increases the depth of one or more openings extending through a stack structure including interleaved first and second dielectric layers by a plurality of etching cycles. Each etch cycle can include one or more dry etch and/or wet etch processes that etch one pair of first and second dielectric layers, i.e., reducing the depth by one dielectric layer pair. The purpose of the chopping process is to make multiple openings at different depths. Accordingly, depending on the number of openings, a certain number of chopping processes, along with a number of chopping masks, may be needed. It is understood that the number of chopping masks, the sequence of the chopping masks, the design (e.g., the number and pattern of openings) of each chopping mask, and/or the reduced depth by each chopping process (e.g., the number of etching cycles) may affect the specific depth of each opening after the chopping process. A detailed description of the chopping process can be referenced in U.S. patent application Ser. No. 16/881,168, filed on May 22, 2022, and U.S. patent application Ser. No. 16/881,339, filed on May 22, 2022, both of which are incorporated by reference in their entireties herein.

Method 900 proceeds to operation 908, as illustrated in FIG. 9, in which a first contact structure is formed in the first contact hole. Method 900 proceeds to operation 910, as illustrated in FIG. 9, in which second contact structures are formed in the second contact holes, respectively, during the formation of the first contact structure.

For example, with reference to FIG. 10C, first spacer 214 may be formed on a sidewall of the first contact hole, and a second spacer 204 may be formed on a sidewall of the second contact hole shown in FIG. 10C. Specifically, first spacer 214 can be formed on the sidewall and a bottom of the first contact hole, and second spacer 204 can be formed on the sidewall and a bottom of the second contact hole, thereby covering first dielectric layers 224 and second dielectric layers 222 exposed from the sidewalls and bottoms of the first and second contact holes. In some implementations, first spacer 214 and second spacer 204 may be formed by depositing dielectric materials, such as silicon oxide, using one or more thin film deposition processes, such as ALD, CVD, PVD, any other suitable processes, or any combination thereof, over the sidewalls and the bottom surfaces of the first and second contact holes.

Then, a portion of first spacer 214 on the bottom of the first contact hole is removed to expose the remainder portion of semiconductor layer 201. A portion of second spacer 204 on the bottom of the second contact hole is also removed to expose second dielectric layer 222A. In some implementations, dry etching can be applied to remove the portion of first spacer 214 on the bottom of the first contact hole and the portion of second spacer 204 on the bottom of the second contact hole. For example, the etching rate, direction, and/or duration of RIE are controlled to etch only the portion of first spacer 214 and the portion of second spacer 204 on the bottom surfaces, but not on the sidewalls, i.e., “punching” through first spacer 214 and second spacer 204 in the z-direction to expose the remainder portion of semiconductor layer 201 and second dielectric layer 222A, respectively.

Subsequently, with reference to FIGS. 10D and 10E, lateral contact structure 206 can be formed below the bottom of the second contact hole. For example, as shown in FIG. 10D, a part of second dielectric layer 222A exposed at the bottom of the second contact hole is removed by wet etching to form a lateral recess 1008. In some implementations, the part of second dielectric layer 222A is wet etched by applying a wet etchant through the second contact hole, creating lateral recess 1008 sandwiched between two first dielectric layers 224. The wet etchant can include phosphoric acid for etching second dielectric layer 222A including silicon nitride. In some implementations, the etching rate and/or etching time are controlled to remove only the part of second dielectric layer 222A that is enough to expose corresponding conductive layer 302A (shown in FIG. 3B) at the same level. Then, lateral recess 1008 may be filled by depositing conductive materials through the second contact hole to form lateral contact structure 206 of FIG. 10E. The conductive materials, such as a metal layer, can be deposited using one or more thin film deposition processes, such as ALD, CVD, PVD, any other suitable processes, or any combination thereof. The deposition rate and/or duration may be controlled to ensure that lateral contact structure 206 can be in contact with the exposed corresponding conductive layer 302A at the same level as lateral recess 1008. In other words, second dielectric layer 222A exposed from the bottom of the second contact hole can be partially replaced with a corresponding lateral contact structure 206 in dielectric portion 107 of connection region 103, while other second dielectric layers 222 at other levels in dielectric portion 107 remain intact.

With reference to FIG. 10E again, first conductor layer 212 may be formed over first spacer 214 and the bottom of the first contact hole. Second conductor layers 202 may be formed over second spacer 204 and lateral contact structure 206. In some implementations, first conductor layer 212 and second conductor layer 202 can be formed in the same process of forming lateral contact structure 206 by depositing the conductive materials not only into lateral recess 1008, but also on the sidewalls and the bottom surfaces of the first and second contact holes, using one or more thin film deposition processes, such as ALD, CVD, PVD, any other suitable processes, or any combination thereof.

With reference to FIG. 10F, a remaining portion of the first contact hole may be filled with first filler body 218. A remaining portion of the second contact hole may be filled with second filler body 208. First and second filler bodies 218, 208, such as dielectric layers, can be deposited using one or more thin film deposition processes, such as ALD, CVD, PVD, any other suitable processes, or any combination thereof. The excess portions of the conductor layers and dielectric layers can be removed by using chemical mechanical polishing (CMP).

With reference to FIG. 10G, first contact pad 220 may be formed on first conductor layer 212 and first filler body 218. Second contact pad 210 may be formed on second conductor layer 202 and second filler body 208. In some implementations, the remainder portion of semiconductor layer 201 under the first contact hole may be removed, and a contact pad 1050 may be formed to fill in the space of the remainder portion of semiconductor layer 201.

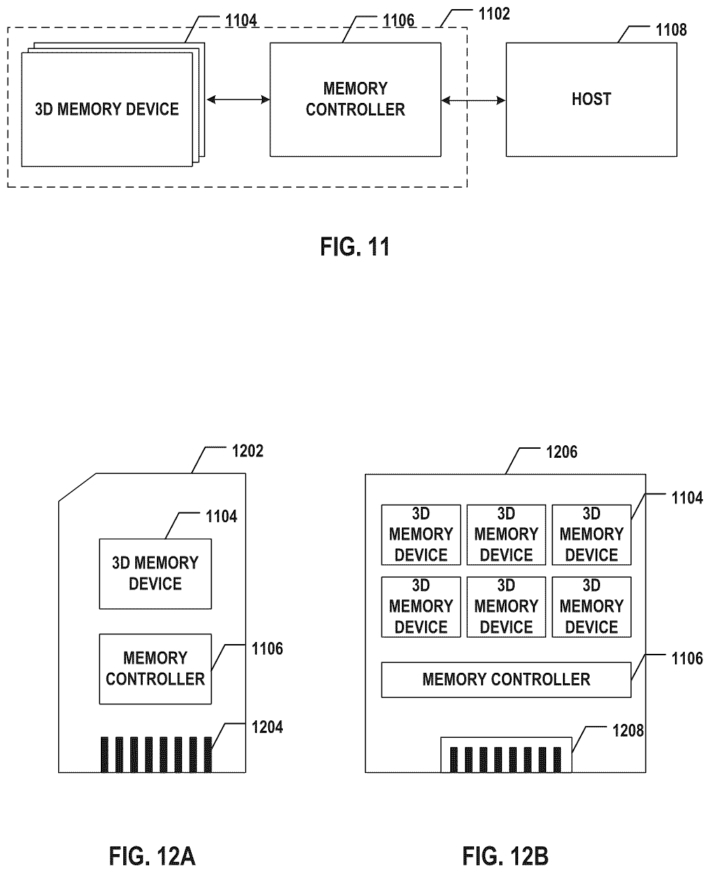

FIG. 11 illustrates a block diagram of an exemplary system 1100 having a 3D memory device, according to some aspects of the present disclosure. System 1100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 11, system 1100 can include a host 1108 and a memory system 1102 having one or more 3D memory devices 1104 and a memory controller 1106. Host 1108 can be a processor of an electronic device, such as a central processing unit (CPU), or a system-on-chip (SoC), such as an application processor (AP). Host 1108 can be configured to send or receive data to or from 3D memory devices 1104.

Memory device 1104 can be any 3D memory device disclosed herein. In some implementations, memory device 1104 includes a NAND Flash memory.

Memory controller 1106 (a.k.a., a controller circuit) is coupled to memory device 1104 and host 1108 and is configured to control memory device 1104, according to some implementations. For example, memory controller 1106 may be configured to operate the plurality of channel structures via the word lines. Memory controller 1106 can manage the data stored in memory device 1104 and communicate with host 1108. In some implementations, memory controller 1106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1106 can be configured to control operations of memory device 1104, such as read, erase, and program operations. Memory controller 1106 can also be configured to manage various functions with respect to the data stored or to be stored in memory device 1104 including, but not limited to bad-block management, garbage collection, logical-to-physical address conversion, wear leveling, etc. In some implementations, memory controller 1106 is further configured to process error correction codes (ECCs) with respect to the data read from or written to memory device 1104. Any other suitable functions may be performed by memory controller 1106 as well, for example, formatting memory device 1104. Memory controller 1106 can communicate with an external device (e.g., host 1108) according to a particular communication protocol. For example, memory controller 1106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1106 and one or more 3D memory devices 1104 can be integrated into various types of storage devices, for example, be included in the same package, such as a universal Flash storage (UFS) package or an eMMC package. That is, memory system 1102 can be implemented and packaged into different types of end electronic products. In one example as shown in FIG. 12A, memory controller 1106 and a single memory device 1104 may be integrated into a memory card 1202. Memory card 1202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1202 can further include a memory card connector 1204 electrically coupling memory card 1202 with a host (e.g., host 1108 in FIG. 11). In another example as shown in FIG. 12B, memory controller 1106 and multiple 3D memory devices 1104 may be integrated into an SSD 1206. SSD 1206 can further include an SSD connector 1208 electrically coupling SSD 1206 with a host (e.g., host 1108 in FIG. 11). In some implementations, the storage capacity and/or the operation speed of SSD 1206 is greater than those of memory card 1202.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A semiconductor device, comprising:
a semiconductor layer;
a stack structure over the semiconductor layer and comprising alternating first layers and first dielectric layers, wherein the stack structure comprises a first portion and a second portion adjacent to the first portion, the first layers of the first portion comprise second dielectric layers, and the first layers of the second portion comprise conductive layers;
a first contact structure extending through the first portion and the semiconductor layer; and
a second contact structure extending through a part of the first portion and connecting with one of the conductive layers.

2. The semiconductor device of claim 1, wherein:
the first contact structure comprises a first segment and a second segment connected with the first segment in a first direction, the first segment comprises a first end contacting the second segment, and the second segment comprises a second end contacting the first segment, wherein a size of the first end is greater than a size of the second end in a second direction perpendicular to the first direction.

3. The semiconductor device of claim 2, wherein the first segment further comprises a third end away from the first end, and the second segment further comprises a fourth end away from the second end, wherein a size of the third end is greater than a size of the first end in the second direction, and a size of the second end is greater than a size of the fourth end in the second direction.

4. The semiconductor device of claim 2, wherein the first segment is located on a side of the second segment away from the semiconductor layer.

5. The semiconductor device of claim 1, wherein:
the second contact structure comprises a vertical contact structure and a lateral contact structure connecting to the vertical contact structure, and the vertical contact structure extends in a same direction as the first contact structure, wherein the lateral contact structure connects with the one of the conductive layers.

6. The semiconductor device of claim 5, wherein:
the first contact structure comprises a first joint in a first stack pair, and the vertical contact structure extends to the first stack pair, wherein the first stack pair is a pair comprising one of the first dielectric layers and one of the first layers in contact with the one of the first dielectric layers.

7. The semiconductor device of claim 6, further comprising a third contact structure extending through a portion of the first portion, wherein the third contact structure is connected with a second stack pair, and the first contact structure comprises a second joint in the second stack pair.

8. The semiconductor device of claim 1, wherein:
the first contact structure comprises a first conductor layer and a first spacer surrounding the first conductor layer; and
the second contact structure comprises a second conductor layer and a second spacer surrounding the second conductor layer, wherein the first spacer and the second spacer comprise a same material, and the first conductor layer and the second conductor layer comprise a same material.

9. The semiconductor device of claim 8, wherein the first contact structure further comprises a first filler body surrounded by the first conductor layer.

10. The semiconductor device of claim 9, wherein the second contact structure further comprises a second filler body surrounded by the second conductor layer, and the first filler body and the second filler body comprise a same material.

11. The semiconductor device of claim 1, further comprising channel structures extending through the second portion into the semiconductor layer.

12. The semiconductor device of claim 11, wherein:
in a vertical direction, a length of the first contact structure is greater than a length of the channel structures.

13. The semiconductor device of claim 11, wherein:
the second portion comprises a first part and a second part separated from the first part, wherein the first portion connects the first part and the second part.

14. The semiconductor device of claim 1, further comprising a peripheral circuit connected with the first contact structure.

15. The semiconductor device of claim 14, further comprising a first connection layer and a second connection layer, the first connection layer connected with the first contact structure, the second connection layer connected with the peripheral circuit,
wherein the first connection layer is bonded with the second connection layer.

16. The semiconductor device of claim 14, wherein the peripheral circuit is disposed under the stack structure, and the first contact structure extends through the semiconductor layer to connect with the peripheral circuit.

17. A memory device, comprising:
a first semiconductor structure, comprising:
a first stack structure comprising alternating first and second dielectric layers; and
a first contact structure extending through the first stack structure;
a second semiconductor structure, comprising:
a second stack structure comprising alternating third and four dielectric layers; and
a second contact structure extending through the second stack structure; and
a first peripheral circuit connected with the first contact structure and the second contact structure.

18. The memory device of claim 17, wherein the first peripheral circuit is bonded with the first semiconductor structure, and the first peripheral circuit comprises a first connect structure between the first semiconductor structure and the second semiconductor structure.

19. The memory device of claim 17, further comprising a second peripheral circuit bonded with the second semiconductor structure, wherein the second peripheral circuit comprises a second connect structure connecting the second contact structure.

20. A method of forming a semiconductor device, comprising:
forming a stack structure comprising alternating first and second dielectric layers;
forming a first contact hole extending through the stack structure; forming second contact holes extending through a part of the stack structure during the formation of the first contact hole;
forming a first contact structure in the first contact hole; and
forming second contact structures in the second contact holes, respectively, during the formation of the first contact structure.
